(19) United States
(12) Patent Application Publication
(10) Pub. No.: US 2018/0069079 A1
(43) Pub. Date: Mar. 8, 2018

(54) SEMICONDUCTOR DEVICES INCLUDING TRAP RICH LAYER REGIONS

(71) Applicant: QUALCOMM Incorporated, San Diego, CA (US)

(72) Inventors: Steve Fanelli, San Marcos, CA (US); Richard Hammond, San Diego, CA (US)

(21) Appl. No.: 15/255,744

(22) Filed: Sep. 2, 2016

(51) Int. Cl. H01L 29/10; H01L 27/12; H01L 21/8234; H01L 21/84; H01L 23/66

(52) U.S. Cl. CPC H01L 29/1083; H01L 27/1203; H04B 1/40; H01L 21/84; H01L 23/66; H01L 21/823493

(57) ABSTRACT

In a particular aspect, a device includes a substrate including a first trap rich layer region and a second trap rich layer region. The first trap rich layer region is separated from the second trap rich layer region by a portion of the substrate. The device further includes a semiconductor device layer including one or more components.

### I. FIELD

The present disclosure is generally related to semiconductor devices that include trap rich layers.

### II. DESCRIPTION OF RELATED ART

Advances in technology have resulted in smaller and more powerful computing devices. For example, a variety of portable personal computing devices, including wireless telephones such as mobile and smart phones, tablets and laptop computers are small, lightweight, and easily carried by users. These devices can communicate voice and data packets over wireless networks. Further, many such devices incorporate additional functionality such as a digital still camera, a digital video camera, a digital recorder, and an audio file player. To enable various functionality, these devices (or components thereof) may include semiconductor devices.

Semiconductor devices, such as the above-referenced semiconductor devices, are often formed on silicon-on-insulator (SOI) substrates or wafers. As part of the formation process, complimentary metal-oxide-semiconductor (CMOS) components are formed and processed on the substrate. For example, semiconductor device components, such as radio frequency (RF) circuitry, may be formed on a substrate. A buried oxide (BOX) layer may be formed in the substrate to isolate the semiconductor device components from a portion of the substrate. The BOX layer may increase parasitic capacitance, causing distortion of RF signals processed by the RF circuitry. To reduce the parasitic capacitance and to reduce RF signal distortion, the semiconductor device components may be formed on a substrate that includes a trap rich layer (e.g., a high resistance polysilicon layer that reduces or prevents conduction). To illustrate, a trap rich layer may be formed by depositing high resistance polysilicon in a substrate as part of a wafer formation process. After the substrate (e.g., the wafer) is formed, one or more semiconductor device components may be formed on the wafer. However, SOI substrates and wafers with trap rich layers are expensive. Additionally, exposing a trap rich layer to high temperatures associated with the CMOS processing may degrade the performance of the trap rich layer. For example, during the CMOS processing stages, temperatures may exceed 1000° Celsius, and exposure to such high temperatures may reduce the effectiveness of the trap rich layer.

Alternatively, one or more semiconductor components of a semiconductor device layer may be formed on a first SOI wafer during one or more CMOS processing stages and, after the CMOS processing stages are complete, the semiconductor device layer (e.g., a layer containing the one or more semiconductor device components) is transferred using a layer transfer process to a second wafer that includes a trap rich layer. Layer transfer processes increase the cost and complexity of manufacturing semiconductor devices.

### III. SUMMARY

In a particular aspect, a device includes a substrate including a first trap rich layer region and a second trap rich layer region. The first trap rich layer region is separated from the second trap rich layer region by a portion of the substrate. The device further includes a semiconductor device layer including one or more components.

In another particular aspect, a method includes forming a first trap rich layer region within a first region of a substrate during a first portion of an energy application process. The method further includes forming a second trap rich layer region within a second region of the substrate during a second portion of the energy application process. The first trap rich layer region is separated from the second trap rich layer region by a portion of the substrate.

In another particular aspect, a method includes forming one or more components of a semiconductor device layer on a first surface of a substrate. The method further includes forming a trap rich layer within the substrate by applying energy through a second surface of the substrate. The second surface is opposite to the first surface.

In another particular aspect, a method includes forming a laser stop layer within a substrate. The method further includes applying a laser to the substrate to form a trap rich layer within the substrate.

Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a block diagram of a particular illustrative aspect of a device that includes one or more trap rich layer regions;

FIG. 2 is a block diagram of a particular illustrative aspect of a device that includes one or more trap rich layer regions and a laser stop layer;

FIGS. 3A-C illustrate stages of a first illustrative process to form a device that includes one or more trap rich layer regions;

FIGS. 4A-B illustrate stages of an illustrative process to form a device that includes a trap rich layer;

FIGS. 5A-C illustrate stages of a second illustrative process to form a device that includes one or more trap rich layer regions;

FIGS. 6A-C illustrate stages of a third illustrative process to form a device that includes one or more trap rich layer regions;

FIGS. 7A-C illustrate stages of a fourth illustrative process to form a device that includes one or more trap rich layer regions;

FIG. 8 is a flow chart that illustrates an illustrative method of forming one or more trap rich layer regions;

FIG. 9 is a flow chart that illustrates an illustrative method of forming a trap rich layer;

FIG. 10 is a flow chart that illustrates an illustrative method of forming a trap rich layer using a stealth dicing laser;

FIG. 11 is a block diagram of a wireless device that includes a semiconductor device including one or more trap rich layer regions; and

FIG. 12 is a data flow diagram of an illustrative aspect of a manufacturing process to fabricate a semiconductor device that includes one or more trap rich layer regions.

### V. DETAILED DESCRIPTION

Particular aspects of the present disclosure are described below with reference to the drawings. In the description, common features are designated by common reference numbers throughout the drawings. As used herein, various terminology is used for the purpose of describing particular implementations only and is not intended to be limiting. For example, the singular forms “a,” “an,” and “the” are intended to include the plural forms as well, unless the context clearly indicates otherwise. It may be further understood that the terms “comprise,” “comprises,” and “comprising” may be used interchangeably with “include,” “includes,” or “including.” Additionally, it will be understood that the term “wherein” may be used interchangeably with “where.” As used herein, “exemplary” may indicate an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to a grouping of one or more elements, and the term “plurality” refers to multiple elements.

The present disclosure describes devices having a substrate that includes a trap rich layer (TRL). The trap rich layer may include high resistance polysilicon and may reduce parasitic capacitance of a buried oxide (BOX) layer included in the substrate. Reducing the parasitic capacitance may reduce distortion of radio frequency (RF) signals processed by one or more semiconductor components of the device, such as RF circuitry or an RF core. In some implementations, the trap rich layer includes multiple separate regions. For example, the substrate may include a first trap rich layer region that is separated from a second trap rich layer region by a portion of the substrate. Because the trap rich layer is divided into regions (as compared to a single trap rich layer that extends from one edge of the substrate to an opposite edge), trap rich layer regions may be formed at locations that benefit from reduced parasitic capacitance. For example, a trap rich layer region may be formed beneath (e.g., under, in a particular orientation) particular components of a semiconductor device layer on the substrate, such as under an RF core or under a gate of a transistor. In this manner, the trap rich layer may be formed in regions of interest (e.g., regions associated with components that may benefit from a trap rich layer region) and not in other regions (e.g., regions associated with components that do not significantly benefit from a trap rich layer region).

The present disclosure also describes methods of forming devices with trap rich layer regions using energy implantation (e.g., a targeted application of energy using an energetic beam). As one example, a method includes forming one or more trap rich layer regions within a substrate by applying energy to one or more separate regions of the substrate, such as via a beam (e.g., an ion beam or a laser beam). For example, a first trap rich layer region and a second trap rich layer may be formed. The first trap rich layer is separated from the second trap rich layer region by a portion of the substrate. The first trap rich layer region may be formed by applying energy to a first region of the substrate, and the second trap rich layer region may be formed by applying energy to a second region of the substrate that is separated from the first region by the portion of the substrate. Because the application of energy may be directed to target regions (as compared to one continuous region), trap rich layer regions that are separated by portions of the substrate may be formed.

In a particular implementation, the trap rich layer regions may be formed using an ion beam. For example, the ion beam may be used to apply energy to regions of the substrate to form trap rich layer regions. In another particular implementation, the trap rich layer regions may be formed using a laser. For example, the laser may be used to apply energy to regions of the substrate to form trap rich layer regions. In a particular implementation, the laser includes a stealth dicing laser. In some implementations, a laser stop layer may be formed within the substrate prior to forming the trap rich layer. For example, one or more dopants may be deposited beneath (e.g., under or below, in a particular orientation) the BOX layer of the substrate to form a laser stop layer. The one or more dopants may include germanium or carbon, as illustrative, non-limiting examples. The laser stop layer may protect the BOX layer, a silicon layer of the substrate, the semiconductor device layer, or a combination thereof, from damage caused by the laser. To illustrate, the one or more dopants may have a different bandgap than silicon, such that a laser that is permeable to silicon is not permeable (or has reduced permeability) to the laser stop layer.

The present disclosure also describes methods of forming devices with a trap rich layer (or trap rich layer regions) after formation of one or more components of a semiconductor device layer. To illustrate, the one or more components of the semiconductor device layer may be formed on a first surface of the substrate using complimentary metal-oxide-semiconductor (CMOS) processing. During the CMOS processing, the substrate may be exposed to high temperatures. After the CMOS processing is complete, energy may be applied (e.g., using an ion beam or a laser) to the substrate to form a trap rich layer or trap rich layer regions. In a particular implementation, the energy is applied to a second surface (e.g., a “backside”) of the substrate that is opposite to the first surface (e.g., the surface that is adjacent to the semiconductor device layer). Applying the energy to the backside of the substrate (instead of a “top” surface of the substrate) may prevent (or reduce) damage to the one or more components from application of the energy (e.g., from the laser or the ion beam).

Because the trap rich layer regions (or the trap rich layer) are formed by applying energy to the backside of the substrate, the trap rich layer may be formed after formation of the one or more components of the semiconductor device layer. For example, the trap rich layer regions may be formed during middle of line (MOL) or back end of line (BEOL) processing stages (e.g., stages that are subsequent to front end of line (FEOL) processing stage, including the CMOS processing stages). Because the trap rich layer regions are formed after the FEOL processing stages, the trap rich layer regions are not exposed to high temperatures that occur during the FEOL processing stages. These high temperatures may damage or reduce the effectiveness of the trap rich layer regions. Thus, the methods of the present disclosure may prevent (or reduce) degradation of trap rich layer regions (or trap rich layers) as compared to methods that expose trap rich layers to high temperatures during FEOL processing stages. Additionally, the methods of the present disclosure may reduce costs and complexity of forming devices having trap rich layers as compared to methods that use wafer-level layer transfer processes.

Although the above-described method includes applying energy to the back side of the substrate, in an alternate implementation, the energy may be applied to the first (e.g., top) surface of the substrate to form the trap rich layer regions. For example, use of some ion beams may not significantly damage the one or more components of the semiconductor device layer, so in this case the energy may be applied to the first surface that is adjacent to the semiconductor device layer. Applying energy to the first surface may use less power if the target regions are closer to the first surface than to the second surface.

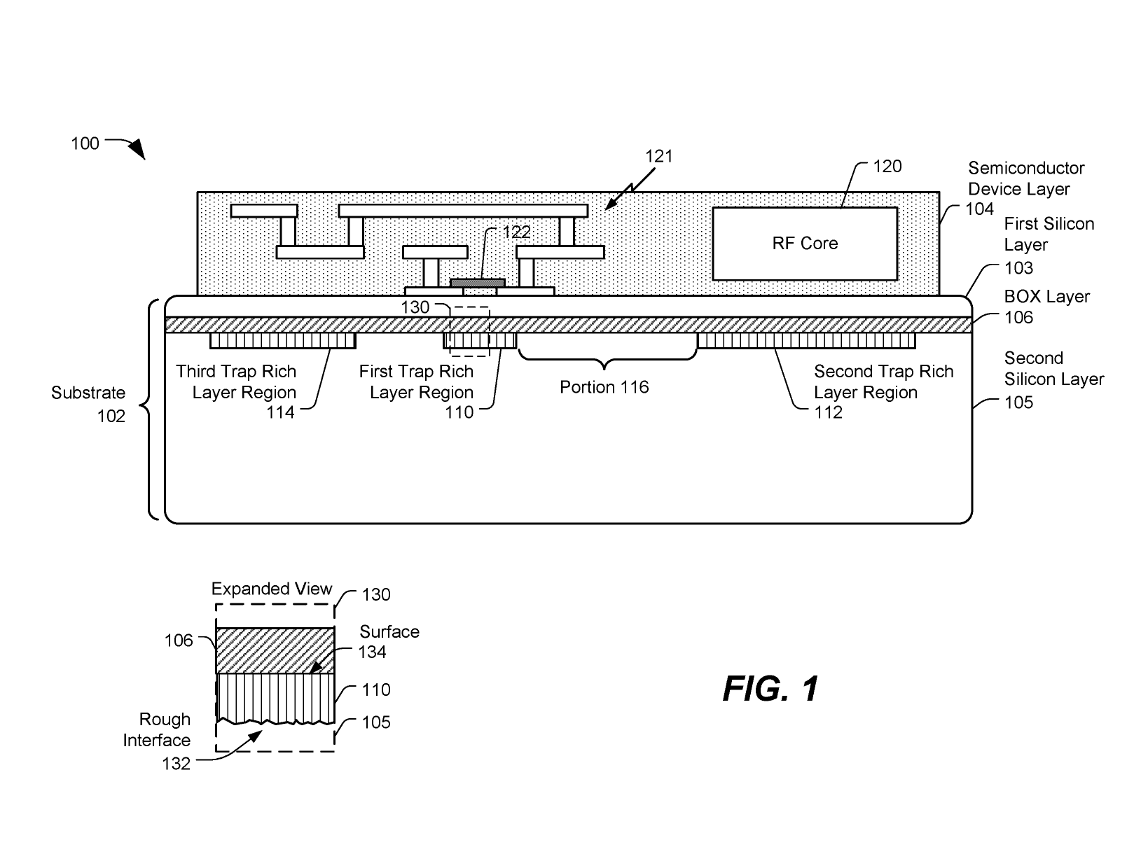

Referring to FIG. 1, a particular illustrative aspect of a device that includes one or more trap rich layer regions is shown and generally designated 100. The device 100 includes a substrate 102 and a semiconductor device layer 104. The substrate 102 may include a silicon on insulator (SOI) substrate or a SOI wafer. The semiconductor device layer 104 includes one or more components, such as a transistor, a capacitor, an inductor, a resistor, a switch, radio frequency (RF) circuitry, vias, wires, metal structures, other components, or a combination thereof. For example, the semiconductor device layer 104 may include an radio frequency (RF) core 120 (e.g., RF circuitry) and a transistor 121, as non-limiting examples. The semiconductor device layer 104 may also be referred to as an “active layer,” a “device layer,” or an “active device layer.” Although referred to as a single layer, in other implementations, the semiconductor device layer 104 may include multiple layers, including device layers and interconnect (e.g., metal) layers. The components of the semiconductor device layer 104 may include one or more complimentary metal-oxide-semiconductor (CMOS) components that are formed during one or more CMOS processing stages. The CMOS processing stages may be part of the front end of line (FEOL) processing stages of the device 100.

The substrate 102 includes a first silicon layer 103, a second silicon layer 105, and a buried oxide (BOX) layer 106. In other implementations, the BOX layer 106 may be replaced with a different insulating layer or dielectric layer. The BOX layer 106 may be implanted, deposited, grown, or formed using any other method of forming an insulating layer within a substrate. The BOX layer 106 may divide the substrate 102 into the first silicon layer 103 and the second silicon layer 105. To illustrate, the BOX layer 106 may be located between the first silicon layer 103 and the second silicon layer 105. The first silicon layer 103 may be located between the BOX layer 106 and the semiconductor device layer 104. The BOX layer 106 may increase parasitic capacitance of the substrate 102. To illustrate, due to operation of one or more components of the semiconductor device layer 104, charge carriers having a first polarity may accumulate along a first surface of the BOX layer 106 (e.g., an upper surface). These charge carriers may cause charge carriers having a second polarity to accumulate along a second surface of the BOX layer 106 (e.g., a lower surface). The accumulation of charge carriers along surfaces of the BOX layer 106 increases a parasitic capacitance. The increased parasitic capacitance may inhibit current flow between source regions and drain regions of transistors of the semiconductor device layer 104, may cause distortion of RF signals processed by one or more components of the semiconductor device layer 104, or both.

The substrate 102 also includes one or more trap rich layer regions. For example, the substrate 102 may include a first trap rich layer region 110, a second trap rich layer region 112, and a third trap rich layer region 114. Although three trap rich layer regions 110-114 are illustrated in FIG. 1, in other implementations, more than three or fewer than three trap rich layer regions are included in the substrate 102. As used herein, a “trap rich layer” region refers to a layer (or region) of a substrate that has a high density of electrically active charge carrier traps. The trap rich layer regions 110-114 are below (e.g., under or beneath) the BOX layer 106 in the orientation illustrated in FIG. 1. Stated another way, the BOX layer 106 is located between the first trap rich layer region 110 and the first silicon layer 103. In a particular implementation, surfaces of the trap rich layer regions 110-114 are in direct contact with the BOX layer 106. For example, a surface 134 of the first trap rich layer region 110 may be in direct contact with the BOX layer 106. In other implementations, the surfaces of the trap rich layer regions 110-114 are not in direct contact with the BOX layer 106 (e.g., a portion of the second silicon layer 105 or another intervening material, such as a dielectric material or other material, may be located between the trap rich layer regions 110-114 and the BOX layer 106).

The trap rich layer regions 110-114 may be separated from other trap rich layer regions by portions of the substrate 102. For example, the first trap rich layer region 110 may be separated from the second trap rich layer region 112 by a portion 116 of the substrate 102 (e.g., a portion of the second silicon layer 105). As another example, the first trap rich layer region 110 may be separated from the third trap rich layer region 114 by a second portion of the substrate 102. Additionally, trap rich layer regions may be separated from outside edges of the substrate 102 by portions of the substrate 102. For example, the second trap rich layer region 112 may be separated from an edge of the substrate 102 by a portion of the substrate 102. Widths of the trap rich layer regions 110-114 may be less than a width of the substrate 102. For example, a width w1 of the first trap rich layer region 110, a width w2 of the second trap rich layer region 112, and a width w3 of the third trap rich layer region 114 may each be less than a width w of the substrate 102. Additionally or alternatively, areas of the trap rich layer regions 110-114 may be less than an area of the substrate 102. In some implementations, thickness of the trap rich layer regions 110-114 is approximately 500-1000 angstroms. In a particular implementation, thickness of the trap rich layer regions 110-114 is approximately 600-700 angstroms.

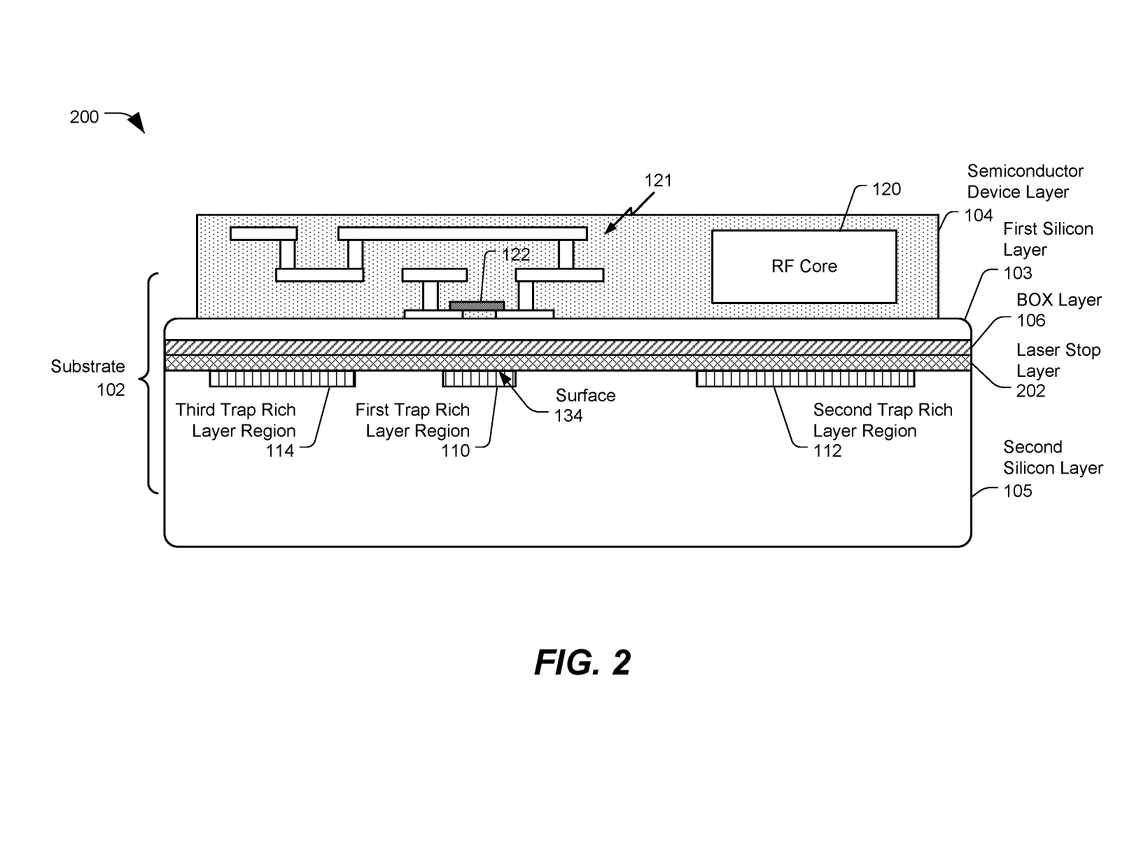

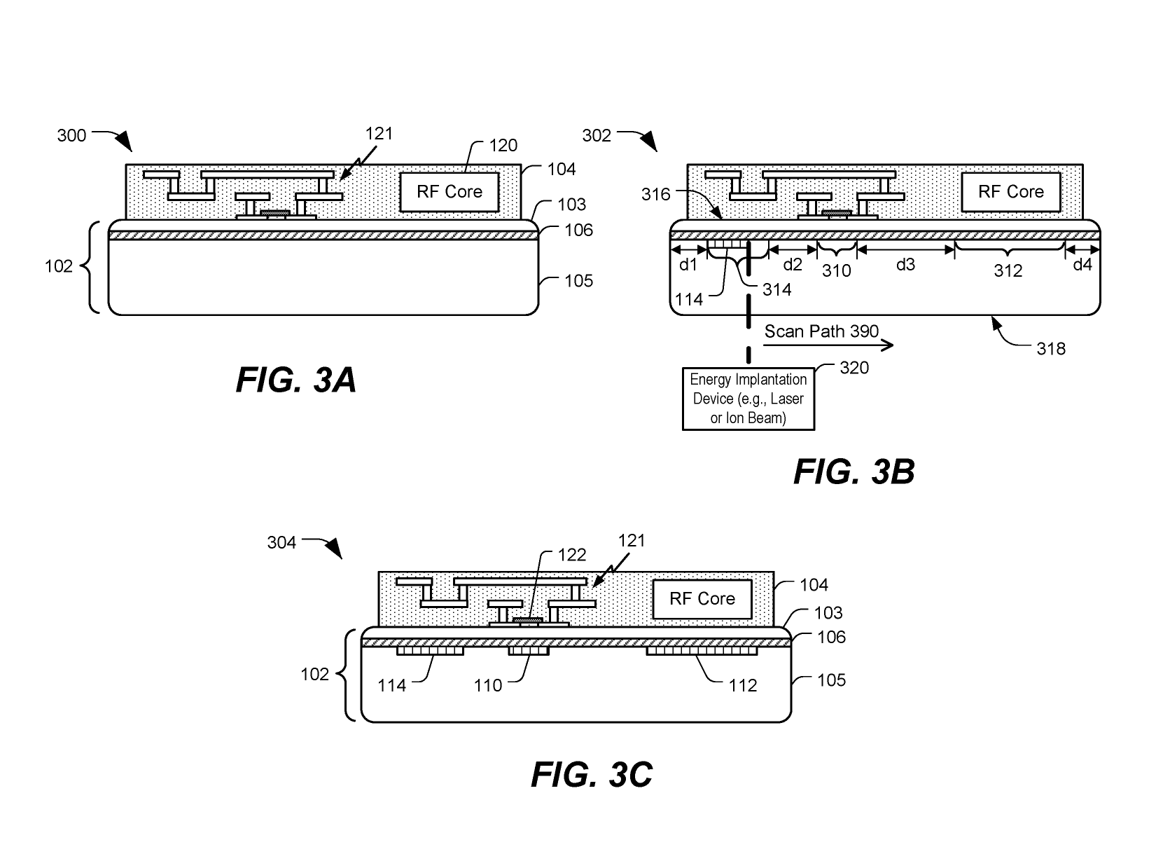

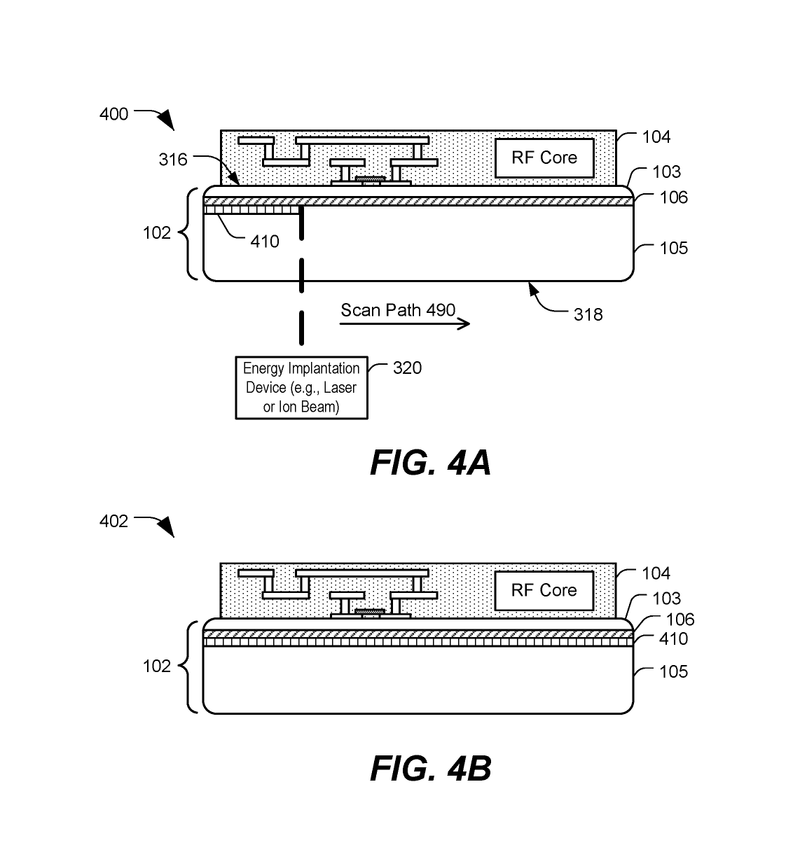

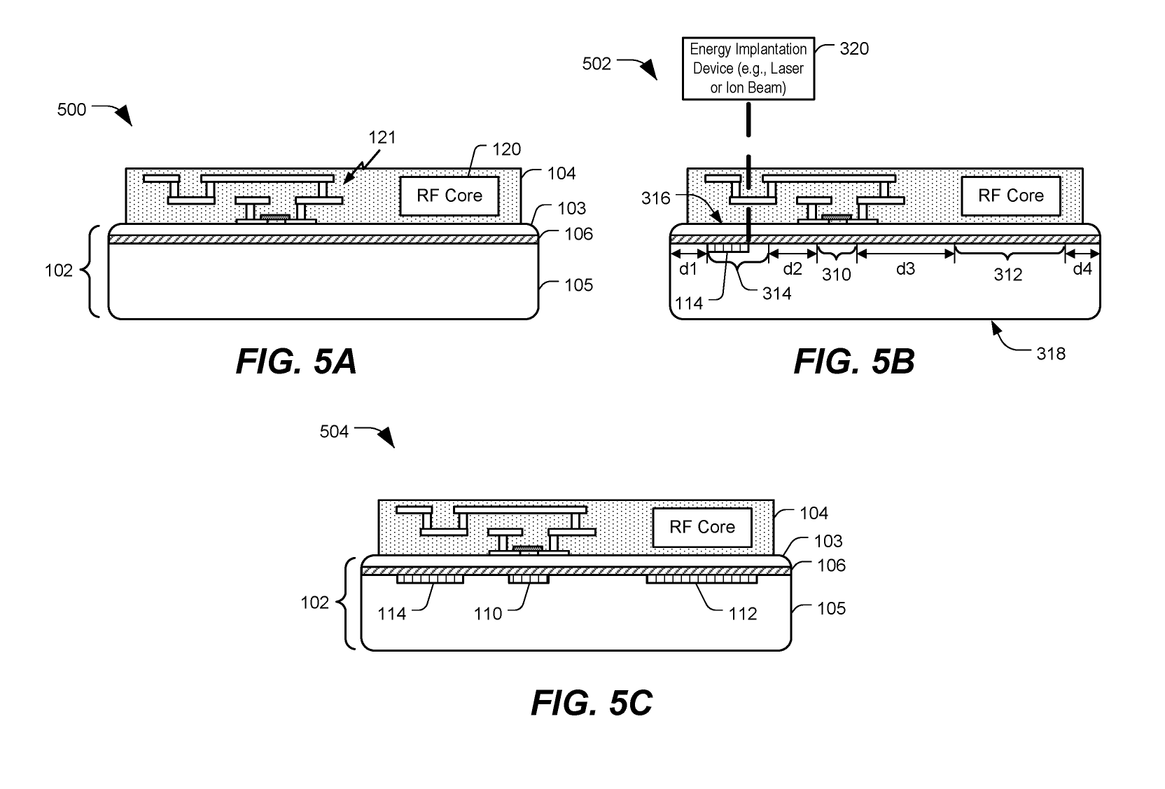

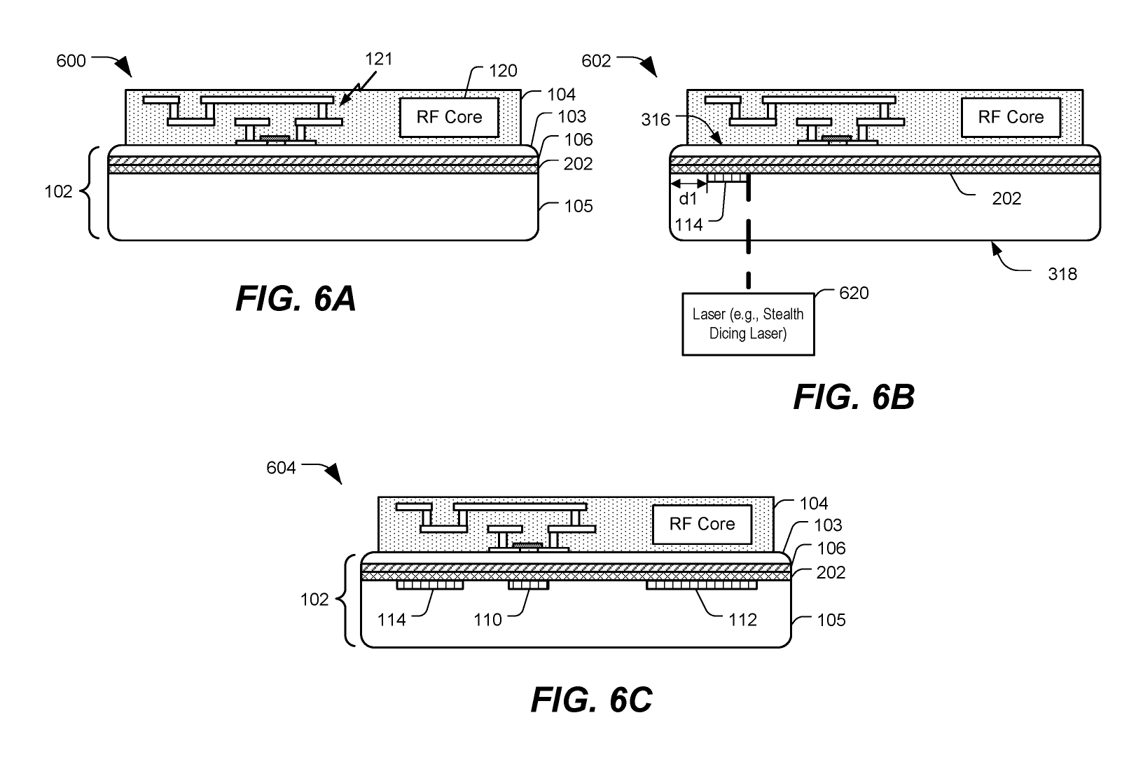

The trap rich layer regions 110-114 may be formed by applying energy to the substrate 102. For example, energy may be applied through a surface of the substrate 102. The surface may be a bottom surface, as further described with reference to FIGS. 3A-3C and 4A-4B. Alternatively, the surface may be a top surface, as further described with reference to FIGS. 5A-5C. In a particular implementation, the trap rich layer regions 110-114 are formed using a laser. For example, a laser may be directed in a scanning pattern across a surface of the substrate. In some implementations, the substrate 102 may further include a laser stop layer, as described with reference to FIGS. 2 and 6A-6C. The laser may include a stealth dicing laser, as a non-limiting example.

A stealth dicing laser refers to a laser that has a wavelength that is permeable to the substrate 102 (e.g., permeable to silicon) and that is focused through an objective lens onto a point on the substrate 102 and can be made to scan along a dicing line. Stealth dicing lasers are sometimes used to cut or dice wafers into semiconductor dies along one or more dicing lines. In some implementations, a second laser may be used to profile a shape of a wafer (or a surface of a wafer) prior to using the stealth laser to form the trap rich layer regions 110-114. For example, a second laser, such as a helium neon laser (e.g., a red laser), may be scanned across a surface of a wafer (e.g., the substrate 102), and light reflected from the surface (due to the second laser) may be analyzed to determine a profile of the wafer. The profile may include x-coordinates and y-coordinates of the wafer, z-coordinates (e.g., a height) of the wafer, total thickness variations of the wafer, a shape of the wafer (e.g., concave or convex, as two non-limiting examples), or a combination thereof. Use of the second laser may be part of a stealth dicing laser process or technique, and the information (e.g., the profile) that is determined may be used to enable depth control of the stealth dicing laser during formation of the trap rich layer regions 110-114 using the stealth dicing laser.

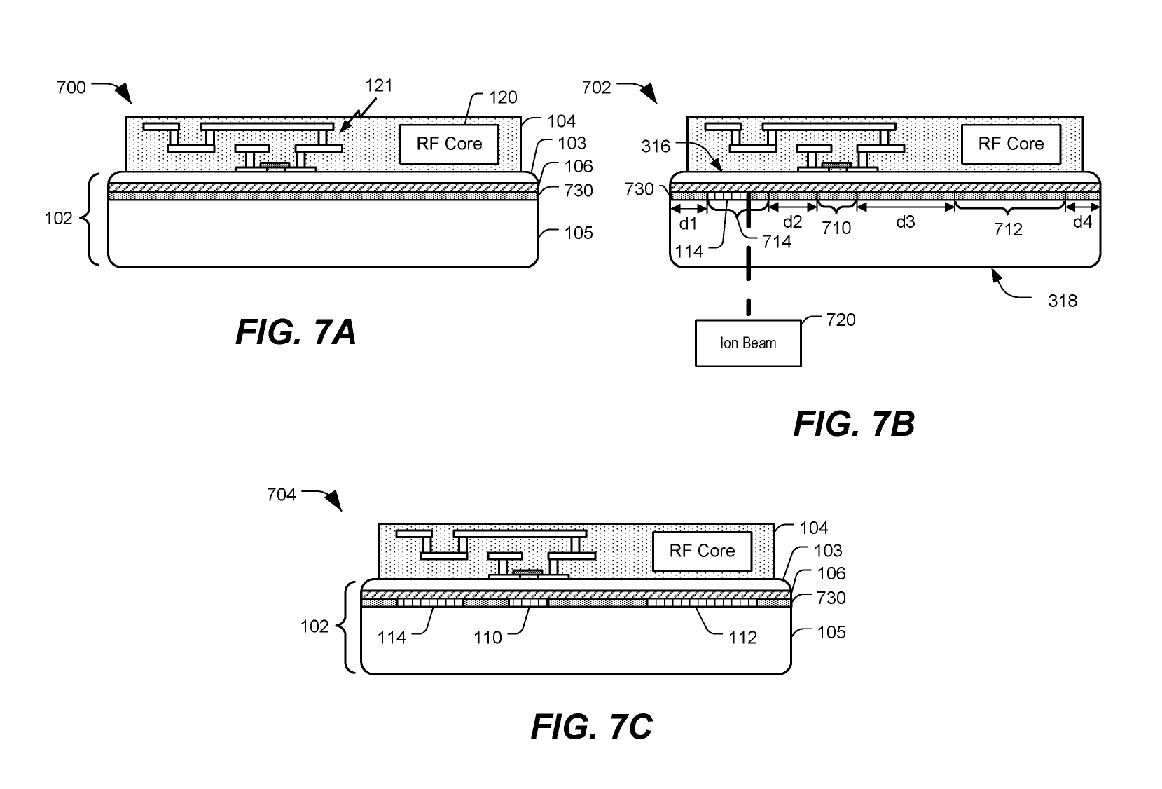

In another particular implementation, the trap rich layer regions 110-114 are formed using an ion beam. For example, an ion beam may be directed across a surface of the substrate 102. In this implementation, the first trap rich layer region 110, the second trap rich layer region 112, and the third trap rich layer region 114 include implanted ions (e.g., ions that are implanted in the substrate 102 by the ion beam). The implanted ions may include germanium, helium, silicon, oxygen, carbon, a noble gas, or other high energy ions or particles. In some implementations, the trap rich layer regions 110-114 may be formed from an ion implant trapper layer, as further described with reference to FIGS. 7A-7C.

The trap rich layer regions 110-114 may be formed after formation of the components of the semiconductor device layer 104, as further described with reference to FIGS. 3A-3C, 4A-4B, and 5A-5C. For example, the energy may be applied (e.g., using a laser or an ion beam) after the one or more CMOS processing stages that form the components of the semiconductor device layer 104. In some implementations, the formation of the trap rich layer regions 110-114 occurs during back end of line (BEOL) processing stages of the device 100 or middle of line (MOL) processing stages of the device 100. Because the trap rich layer regions 110-114 may be formed after the formation of the components of the semiconductor device layer 104, the trap rich layer regions 110-114 may not be exposed to high temperatures associated with the FEOL processing stages (e.g., the CMOS processing stages). For example, during the FEOL processing stages, the substrate 102 may be exposed to temperatures of 1000° Celsius (C) and above. Exposing the trap rich layer regions 110-114 to these high temperatures may degrade the effectiveness of the trap rich layer regions 110-114. For example, exposing the trap rich layer regions 110-114 to high temperatures may reduce the density and number of charge carrier traps within the trap rich layer regions 110-114. Because the trap rich layer regions 110-114 are not exposed to these high temperatures, the trap rich layer regions 110-114 may be more effective (e.g., may better prevent or reduce parasitic capacitance) than trap rich layers that are exposed to high temperatures. In some implementations, the trap rich layer regions 110-114 may be formed at any time between a beginning of FEOL processing stages and an end of BEOL processing stages. For example, the trap rich layer regions 110-114 may be formed during FEOL processing stages (e.g., after high temperature processing stages are complete), during MOL processing stages, or during BEOL processing stages, as non-limiting examples.

The trap rich layer regions 110-114 may include a high resistance polysilicon layer. For example, application of energy (e.g., using a laser or an ion beam) may heat up silicon in a region of the substrate 102 and damage (e.g., melt or “re-melt”) the silicon, which increases a resistance of the region of the substrate 102 and forms polysilicon within the region of the substrate 102. Thus, applying energy to regions of the substrate 102 (e.g., regions corresponding to the trap rich layer regions 110-114) causes formation of high resistance polysilicon layer regions within the substrate 102. These high resistance polysilicon layer regions are referred to as trap rich layer regions because the high resistance polysilicon layer regions have a high density of electrically active charge carrier traps.

Due to the damage (e.g., damage associated with the application of energy from the laser or the ion beam) caused to regions of the substrate 102 to form the trap rich layer regions 110-114, the trap rich layer regions 110-114 may have a rough (e.g., jagged or non-smooth) interface with the second silicon layer 105. For example, as illustrated in an expanded view 130 in FIG. 1, the first trap rich layer region 110 may have a rough interface 132 with the second silicon layer 105. To illustrate, the surface 134 (e.g., a top surface in the orientation illustrated in FIG. 1) may be in contact with the BOX layer 106, and a second surface (e.g., a bottom surface in the orientation illustrated in FIG. 1) of the first trap rich layer region 110 may be rough (e.g., not substantially smooth or flat) due to damage caused by application of energy, such as energy applied using a laser or an ion beam, as non-limiting examples.

The location of the trap rich layer regions 110-114 may be selected (e.g., during a design process) such that the first silicon layer 103 is located between the trap rich layer regions 110-114 and a component of the semiconductor device layer 104. For example, the first silicon layer 103 may be located between the first trap rich layer region 110 and a gate 122 of the transistor 121. Stated another way, the first trap rich layer region 110 may be beneath (e.g., under or below) the gate 122, in the orientation illustrated in FIG. 1. As another example, the first silicon layer 103 may be located between the second trap rich layer region 112 and the RF core 120. Stated another way, the second trap rich layer region 112 may be beneath the RF core 120. As another example, the first silicon layer 103 may be located between the third trap rich layer region 114 and a component of the semiconductor device layer 104, such as a trench (not illustrated). The trench may extend through a portion of the semiconductor device layer 104 and a portion of the substrate 102 (e.g., a portion of the first silicon layer 103). Forming the trap rich layer regions 110-114 in specific locations (e.g., beneath components which benefit from the trap rich layer regions 110-114) may cost less than forming a trap rich layer that extends the entirety of the substrate 102.

The trap rich layer regions 110-114 may be configured to prevent (or reduce) parasitic capacitance of the substrate 102, which may improve performance of the components of the semiconductor device layer 104 that are above the trap rich layer regions 110-114 in the orientation illustrated in FIG. 1. To illustrate, due to operation of the one or more components of the semiconductor device layer 104, charge carriers may accumulate along a surface (e.g., an upper surface) of the BOX layer 106. The trap rich layer regions 110-114 are configured to prevent (or reduce) the accumulation of charge carriers along a second surface (e.g., a lower surface) of the BOX layer 106. To illustrate, the charge carrier traps within the trap rich layer regions 110-114 inhibit (or reduce) the accumulation of charge carriers along the second surface of the BOX layer 106 by trapping the charge carriers within the trap rich layer regions 110-114. Preventing (or reducing) the accumulation of charge carriers along the second surface of the BOX layer 106 reduces (or eliminates) parasitic capacitance of the substrate 102 that affects components of the semiconductor device layer 104. For example, the first trap rich layer region 110 may reduce or eliminate parasitic capacitance that affects the transistor 121, thereby improving operation of the transistor 121. As another example, the second trap rich layer region 112 may reduce or eliminate parasitic capacitance that affects the RF core 120, thereby reducing RF signal distortion at the RF core 120.

In a particular implementation, the substrate 102 and the semiconductor device layer 104 are integrated in a transceiver. For example, the transistor 121 and the RF core 120 may be part of RF circuitry of the transceiver. The transceiver may experience reduced RF signal distortion due to the presence of the trap rich layer regions 110-114. The transceiver may be included in a mobile device, such as a mobile phone, a tablet computer, a laptop computer, a personal digital assistant (PDA), another device, or a combination thereof, as non-limiting examples. Alternatively, the transceiver may be included in a base station. In other implementations, the substrate 102 and the semiconductor device layer 104 may be integrated in other components of a mobile device (or a base station), such as a transmitter, a receiver, or a processor, as non-limiting examples.

Thus, the device 100 of FIG. 1 may have reduced parasitic capacitance associated with the substrate 102 due to the presence of the trap rich layer regions 110-114. To illustrate, the charge carrier traps within the trap rich layer regions 110-114 may inhibit (or reduce) the accumulation of charge carriers along a surface (e.g., a lower surface) of the BOX layer 106, which reduces (or eliminates) parasitic capacitance of the substrate 102. Reducing or eliminating parasitic capacitance may improve operation of one or more of the components of the semiconductor device layer 104. For example, RF signal distortion at the RF core 120 may be reduced. Forming the trap rich layer regions 110-114 by applying energy (e.g., using a laser or an ion beam) reduces costs as compared to using a wafer-level layer transfer process. Additionally, the trap rich layer regions 110-114 may be formed after the FEOL processing stages, which prevents the trap rich layer regions 110-114 from being exposed to high temperatures during the FEOL processing stages. Preventing the trap rich layer regions 110-114 from being exposed to high temperatures during FEOL processing stages improves effectiveness of the trap rich layer regions 110-114 as compared to trap rich layers that are degraded by exposure to high temperatures during FEOL processing stages.

Referring to FIG. 2, a particular illustrative aspect of a device that includes one or more trap rich layer regions and a laser stop layer is shown and generally designated 200. The device 200 includes the substrate 102 and the semiconductor device layer 104, and the substrate 102 includes the first silicon layer 103, the second silicon layer 105, the BOX layer 106, and the trap rich layer regions 110-114, as described with reference to FIG. 1. The trap rich layer regions 110-114 may be formed using a laser, such as an infrared or stealth dicing laser. The laser may be applied to the bottom side of the substrate 102 (e.g., to the second silicon layer 105).

The substrate 102 of the device 200 further includes a laser stop layer 202. The laser stop layer 202 may be located between the trap rich layer regions 110-114 and the semiconductor device layer 104. To illustrate, the laser stop layer 202 may be located between the trap rich layer regions 110-114 and the BOX layer 106. In a particular implementation, surfaces of the trap rich layer regions 110-114 are in direct contact with the laser stop layer 202. For example, the surface 134 (e.g., the top surface) of the first trap rich layer region 110 may be in direct contact with the laser stop layer 202. In other implementations, the surfaces of the trap rich layer regions 110-114 may not be in direct contact with the laser stop layer 202 (e.g., portions of the second silicon layer 105 may be located between the trap rich layer regions 110-114 and the laser stop layer 202, as a non-limiting example).

The laser stop layer 202 may include at least one dopant. The at least one dopant may include germanium. Additionally or alternatively, the at least one dopant may include carbon. In other implementations, the at least one dopant may include other dopants that have a different bandgap than silicon.

The laser stop layer 202 may be configured to prevent a laser that is applied through a bottom surface of the substrate 102 from reaching the BOX layer 106, or to reduce an amount or magnitude of the beam energy of the laser that reaches the BOX layer 106. To illustrate, the laser stop layer 202 may include germanium. Germanium has a different bandgap than silicon. Because of the different bandgap, a laser having a wavelength that is permeable to silicon may not be permeable to germanium. Thus, a laser having a wavelength that is permeable to the substrate 102 (e.g., that is permeable to silicon) may not be permeable to the laser stop layer 202. Because the laser is not permeable to the laser stop layer 202, the laser stop layer 202 may prevent the beam energy of the laser from reaching the BOX layer 106, or may reduce a magnitude of the beam energy of the laser that reaches the BOX layer 106. Preventing the beam energy of the laser from reaching the BOX layer 106 (or reducing the magnitude of the beam energy of the laser that reaches the BOX layer 106) may reduce a temperature of the BOX layer 106 during formation of the trap rich layer regions 110-114, which reduces a risk of damage to the BOX layer 106 from the laser (e.g., from high temperatures caused by the laser).

Thus, the device 200 of FIG. 2 reduces a risk of damage to the BOX layer 106, as compared to other devices that do not include a laser stop layer. To illustrate, the laser stop layer 202 prevents a laser from reaching the BOX layer 106 (or reduces a magnitude of the beam energy of the laser that reaches the BOX layer 106). Preventing the laser from reaching the BOX layer 106 reduces a risk of damage to the BOX layer 106 from being heated by the laser. Thus, damage to the BOX layer 106 during formation of the trap rich layer regions 110-114 is reduced or eliminated, which improves the effectiveness of the BOX layer 106.

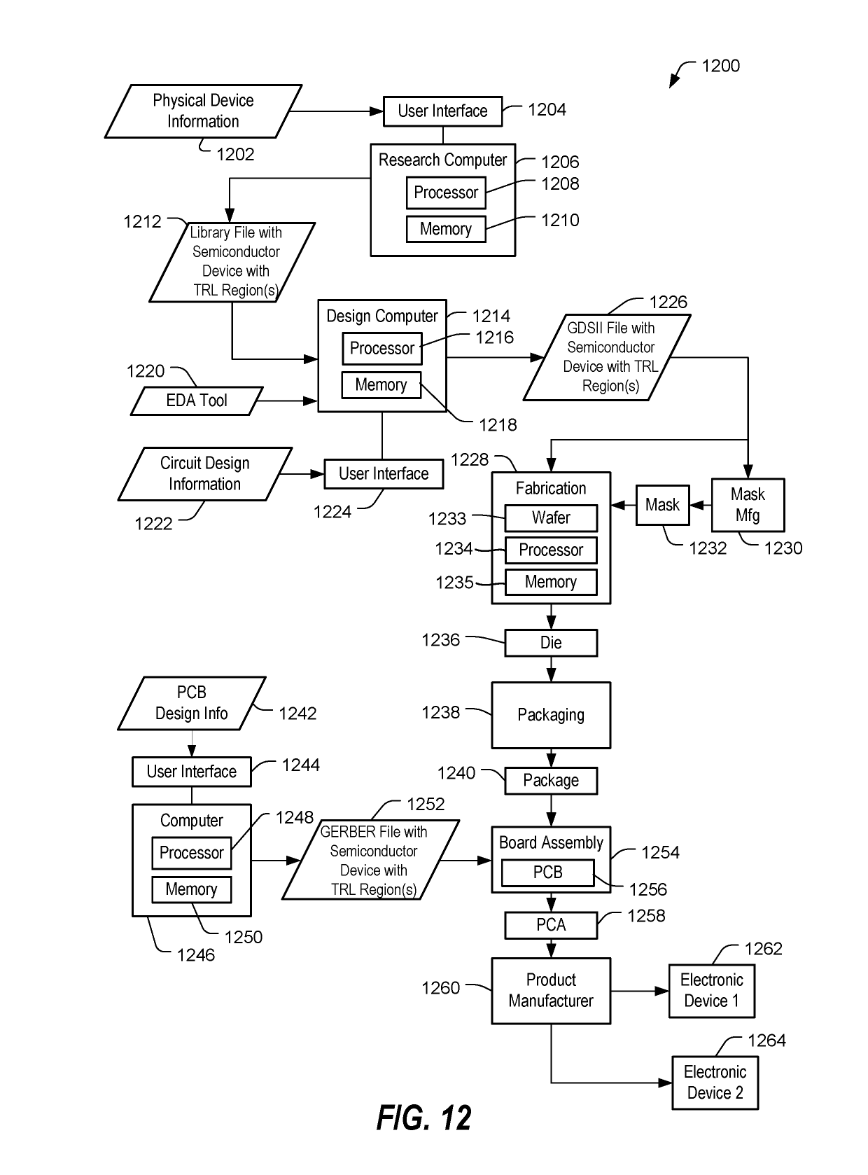

FIGS. 3A-C illustrate stages of a first illustrative process to form a device that includes one or more trap rich layer regions. In a particular implementation, the device includes the device 100 of FIG. 1. In a particular implementation, the steps of the process may be initiated and/or performed by one or more devices described with reference to FIG. 12.

Referring to FIG. 3A, a first illustrative diagram of at least one stage of a first illustrative process to form a device that includes one or more trap rich layer regions is shown and designated 300. As illustrated in FIG. 3A, the substrate 102 may include the first silicon layer 103, the BOX layer 106, and the second silicon layer 105. One or more components of the semiconductor device layer 104, such as the transistor 121 or the RF core 120, may be formed on the substrate 102 as part of one or more CMOS processing stages or FEOL processing stages. The one or more components of the semiconductor device layer 104 may be formed prior to forming trap rich layer regions, as further described with reference to FIGS. 3B and 3C.

Referring to FIG. 3B, a second illustrative diagram of at least one stage of the first process to form the device including one or more trap rich layer regions is shown and designated 302. As illustrated in FIG. 3B, one or more trap rich layer regions may be formed by applying energy to regions of the substrate 102. For example, the first trap rich layer region 110 may be formed by applying energy to a first region 310 of the substrate 102, the second trap rich layer region 112 may be formed by applying energy to a second region 312 of the substrate 102, and the third trap rich layer region 114 may be formed by applying energy to a third region 314 of the substrate 102. The first region 310 may be separated from the second region 312 by a distance d3, and the first region 310 may be separated from the third region 314 by a distance d2.

The energy may be applied by an energy implantation device 320. For example, the energy implantation device 320 may be configured to apply energy to the regions 310-314 of the substrate 102 during an energy application process. A portion of the energy application process may correspond to formation of each trap rich layer region, and each portion of the energy application process may be distinct (e.g., separate). To illustrate, the energy implantation device 320 may be directed at the first region 310 to form the first trap rich layer region 110 during a first portion of the energy application process, the energy implantation device 320 may be directed at the second region 312 to form the second trap rich layer region 112 during a second portion of the energy application process, and the energy implantation device 320 may be directed at the third region 314 to form the third trap rich layer region 114 during a third portion of the energy application process. Between each portion of the energy application process, the energy implantation device 320 may move along a path without applying energy (e.g., the energy implantation device 320 may follow a scan path 390 along a surface of the substrate 102 and may selectively activate or de-activate a beam based on a position of the energy implantation device 320 relative to the regions 310-314). In this manner, trap rich layer regions may be formed that are separated by portions of the substrate 102. For example, the first trap rich layer region 110 may be separated from the second trap rich layer region 112 by the portion 116 of the substrate 102, as described with reference to FIG. 1.

Although the portions of the energy application process are described as first, second, and third portions, the portions may occur in any order. For example, in the implementation illustrated in FIG. 3, energy is applied to the first region 310 subsequent to energy being applied to the third region 314, and energy is applied to the second region 312 subsequent to energy being applied to the first region 310. Additionally, the regions 310-314 may not be aligned with edges of the substrate 102. For example, the third region 314 may be separated from a left edge of the substrate 102 by a distance d1, and the second region 312 may be separated from a right edge of the substrate 102 by a distance d4. Thus, trap rich layer regions may be formed that are not aligned with the edges of the substrate 102.

The energy implantation device 320 may be configured to apply energy through a particular surface of the substrate 102. As illustrated in FIG. 3B, the energy may be applied through a “backside” of the substrate 102 to the regions 310-314. To illustrate, the semiconductor device layer 104 may be formed on a first surface 316 (e.g., a top surface) of the substrate 102, and the energy may be applied through a second surface 318 (e.g., a bottom surface) that is opposite to the first surface 316. The second surface 318 may be referred to as the backside of the substrate 102. Applying energy through the second surface 318 may avoid potential damage to the one or more components of the semiconductor device layer 104 that may occur if the energy is applied through the first surface 316. In some implementations, the energy may be applied through the second surface 318 after the substrate 102 has been grinded and polished (e.g., after the substrate 102, specifically the second silicon layer 105, is thinned).

In a particular implementation, the energy implantation device 320 includes or corresponds to a laser. For example, the energy implantation device 320 may be a stealth dicing laser, an infrared laser, or another type of laser, and the trap rich layer regions 110-114 may be formed using the laser. To illustrate, applying the energy to the regions 310-314, as described above, may include applying a laser beam to the regions 310-314 to form the trap rich layer regions 110-114. For example, the laser beam may have a wavelength that is permeable to the second silicon layer 105, and the laser may heat up the regions 310-314 to cause the regions 310-314 to melt, forming the trap rich layer regions 110-114, as described with reference to FIG. 1.

In another particular implementation, the energy implantation device 320 includes an ion beam. For example, the energy implantation device 320 may be an ion beam emitter that is configured to implant one or more ions or charged particles within the substrate 102, and the trap rich layer regions 110-114 may be formed using the ion beam. To illustrate, applying the energy to the regions 310-314, as described above, may include applying an ion beam to the regions 310-314 to form the trap rich layer regions 110-114. For example, the ion beam may implant one or more ions (or other charged particles) that heat up the regions 310-314 and cause the regions 310-314 to melt, forming the trap rich layer regions 110-114, as described with reference to FIG. 1. Thus, the energy application process may include or correspond to a beam application process (e.g., using a laser beam or an ion beam).

Referring to FIG. 3C, a third illustrative diagram of at least one stage of the first process to form the device including one or more trap rich layer regions is shown and designated 304. As illustrated in FIG. 3C, after the energy is applied to the regions 310-314 by the energy implantation device 320, the trap rich layer regions 110-114 are formed. The trap rich layer regions 110-114 may be formed at locations that are beneath particular components of the semiconductor device layer 104 that benefit from a reduction in parasitic capacitance, as described with reference to FIG. 1. For example, the first trap rich layer region 110 may be formed beneath the gate 122 of the transistor 121 (e.g., after formation of the first trap rich layer region 110, the first silicon layer 103 may be located between the first trap rich layer region 110 and the gate 122), and the second trap rich layer region 112 may be formed beneath the RF core 120 (e.g., after formation of the second trap rich layer region 112, the first silicon layer 103 may be located between the second trap rich layer region 112 and the RF core 120).

With reference to FIGS. 3A-3C, the formation of the trap rich layer regions 110-114 using the energy implantation device 320 is described as occurring subsequent to the formation of the one or more components of the semiconductor device layer 104. In other implementations, the one or more components of the semiconductor device layer 104 may be formed subsequent to the formation of the trap rich layer regions 110-114. For example, the trap rich layer regions 110-114 may be formed during one or more FEOL processing stages and prior to one or more CMOS processing stages used to form the one or more components of the semiconductor device layer 104. Forming the trap rich layer regions 110-114 prior to forming the one or more components may reduce complexity of MOL or BEOL processing stages at the cost of potentially degrading the effectiveness of the trap rich layer regions 110-114.

The process of forming a device including one or more trap rich layer regions described with reference to FIGS. 3A-3C may improve operation of one or more components of the semiconductor device layer 104. For example, forming the trap rich layer regions 110-114 may reduce (or eliminate) parasitic capacitance of the substrate 102, which reduces RF signal distortion or otherwise improves performance at the one or more components. Forming the trap rich layer regions 110-114 using the energy implantation device 320 (e.g., using a laser or an ion beam) reduces costs as compared to bonding a semiconductor device layer to a different substrate having a trap rich layer using a wafer-level layer transfer process. Additionally, because the trap rich layer regions 110-114 are formed by applying energy through the second surface 318 (e.g., the backside of the substrate 102), the trap rich layer regions 110-114 may be formed after the FEOL processing stages without damaging the one or more components of the semiconductor device layer 104. Forming the trap rich layer regions 110-114 after the FEOL processing stages prevents the trap rich layer regions 110-114 from suffering degradation caused by exposure to high temperatures during FEOL processing stages.

FIGS. 4A-B illustrate stages of an illustrative process to form a device that includes a trap rich layer. In a particular implementation, the steps of the process may be initiated and/or performed by one or more devices described with reference to FIG. 12.

Referring to FIG. 4A, a first illustrative diagram of at least one stage of the illustrative process to form a device that includes a trap rich layer is shown and designated 400. The stage 400 may occur subsequent to the at least one stage illustrated in FIG. 3A. As illustrated in FIG. 4A, the energy implantation device 320 may apply energy across a width of the substrate 102 to form a single trap rich layer 410. In FIG. 4A, the energy implantation device 320 may begin applying energy at a first edge (e.g., a left edge) of the substrate 102, and the energy implantation device 320 may apply energy during an entirety of the energy implantation process. For example, the energy implantation device 320 may apply energy following a scan path 490 along the second surface 318 of the substrate 102 until the energy implantation device 320 reaches a second edge (e.g., a right edge) of the substrate 102.

Referring to FIG. 4B, a second illustrative diagram of at least one stage of the process to form the device including a trap rich layer is shown and designated 402. As illustrated in FIG. 4B, the trap rich layer 410 may be formed. The trap rich layer 410 may extend across an entirety of the substrate 102. To illustrate, a width of the trap rich layer 410 may be the same as a width of the substrate 102. The trap rich layer 410 may reduce parasitic capacitance associated with the substrate 102, thereby improving operation of components within an entirety of the semiconductor device layer 104. Although the trap rich layer 410 is illustrated as spanning the entire width of the substrate 102, in other implementations, the trap rich layer 410 may not be aligned with or extend to the edges of the substrate 102 (e.g., portion(s) of the second silicon layer 105 may separate the trap rich layer 410 from the edge(s) of the substrate 102). In these implementations, the width of the trap rich layer 410 is less than the width of the substrate 102. A trap rich layer 410 having a smaller width than the substrate 102 may be formed in implementations where the semiconductor device layer 104 has a width that is smaller than the width of the substrate 102.

In the implementation illustrated in FIGS. 4A-4B, the trap rich layer 410 is formed subsequent to the one or more components of the semiconductor device layer 104. Thus, the trap rich layer 410 may not be degraded by high temperatures associated with FEOL processing stages, such as one or more CMOS processing stages, that are used to form the one or more components of the semiconductor device layer 104. In other implementations, the trap rich layer 410 may be formed prior to formation of the one or more components of the semiconductor device layer 104.

The process of forming a device including a trap rich layer described with reference to FIGS. 4A-4B may form a trap rich layer 410 that reduces parasitic capacitance associated with the substrate 102, thereby improving performance of one or more components of the semiconductor device layer 104.

FIGS. 5A-C illustrate stages of a second illustrative process to form a device that includes one or more trap rich layer regions. In a particular implementation, the device includes the device 100 of FIG. 1. In a particular implementation, the steps of the process may be initiated and/or performed by one or more devices described with reference to FIG. 12.

Referring to FIG. 5A, a first illustrative diagram of at least one stage of a second illustrative process to form a device that includes one or more trap rich layer regions is shown and designated 500. As illustrated in FIG. 5A, the substrate 102 may include the first silicon layer 103, the BOX layer 106, and the second silicon layer 105. One or more components of the semiconductor device layer 104, such as the transistor 121 or the RF core 120, may be formed on the substrate 102 as part of one or more CMOS processing stages or FEOL processing stages.

Referring to FIG. 5B, a second illustrative diagram of at least one stage of the second process to form the device including one or more trap rich layer regions is shown and designated 502. Energy is applied to the regions 310-314 of the substrate 102 to form the trap rich layer regions 110-114, as described with reference to FIG. 3B. However, in contrast to FIG. 3B, the energy implantation device 320 applies energy through the first surface 316 (e.g., the top surface) of the substrate 102. Thus, in FIG. 3B, energy is applied through the same surface of the substrate 102 that the semiconductor device layer 104 is formed on (e.g., the first surface 316). In a particular implementation, the energy implantation device 320 generates an ion beam, and the ion beam does not cause significant damage to the one or more components of the semiconductor device layer 104. In an alternate implementation, the energy implantation device 320 includes a laser, and the laser has a wavelength that is permeable to the one or more components of the semiconductor device layer 104 so that the laser beam does not cause significant damage to the one or more components of the semiconductor device layer 104. In other implementations, to avoid damage to the one or more components of the semiconductor device layer 104, the trap rich layer regions 110-114 may be formed prior to formation of the one or more components of the semiconductor device layer 104.

Referring to FIG. 5C, a third illustrative diagram of at least one stage of the second process to form the device including one or more trap rich layer regions is shown and designated 504. As illustrated in FIG. 5C, after the energy implantation device 320 applies energy to the regions 310-314, the trap rich layer regions 110-114 are formed within the substrate 102.

The process of forming a device including one or more trap rich layer regions described with reference to FIGS. 5A-5C may form trap rich layer regions using reduced power as compared to the processes described with reference to FIGS. 3A-3C and 4A-4B. To illustrate, a thickness of the first silicon layer 103 (or a thickness of both the first silicon layer 103 and the semiconductor device layer 104) may be less than a thickness of the second silicon layer 105. Applying energy through a surface that is closer to the regions 310-314 (e.g., the target regions) reduces power consumption of the energy implantation device 320. Thus, applying energy through the top (e.g., the first surface 316) of the substrate 102 to form the trap rich layer regions 110-114 may use less power than applying energy through the backside (e.g., the second surface 318) of the substrate 102 to form the trap rich layer regions 110-114.

FIGS. 6A-C illustrate stages of a third illustrative process to form a device that includes one or more trap rich layer regions. In a particular implementation, the device includes the device 200 of FIG. 2. In a particular implementation, the steps of the process may be initiated and/or performed by one or more devices described with reference to FIG. 12.

Referring to FIG. 6A, a first illustrative diagram of at least one stage of a third illustrative process to form a device that includes one or more trap rich layer regions is shown and designated 600. As illustrated in FIG. 6A, the substrate 102 may include the first silicon layer 103, the BOX layer 106, and the second silicon layer 105. Additionally, the laser stop layer 202 may be formed within the substrate 102. For example, one or more dopants may be implanted (e.g., deposited) in the substrate 102 to form the laser stop layer 202. The one or more dopants may include germanium, carbon, one or more other dopants, or a combination thereof. As described with reference to FIG. 2, a bandgap of the one or more dopants is different than a bandgap of silicon. The laser stop layer 202 may be formed beneath the BOX layer 106 (e.g., the laser stop layer 202 may be located between the BOX layer 106 and the second silicon layer 105). In a particular implementation, the laser stop layer 202 may be formed in direct contact with the BOX layer 106. The laser stop layer 202 may be formed prior to forming the trap rich layer regions 110-114, as further described with reference to FIG. 6B. One or more components of the semiconductor device layer 104, such as the transistor 121 or the RF core 120, may be formed on the substrate 102 as part of one or more CMOS processing stages or FEOL processing stages.

Referring to FIG. 6B, a second illustrative diagram of at least one stage of the first process to form the device including one or more trap rich layer regions is shown and designated 602. As illustrated in FIG. 6B, a laser 620 applies a laser beam to the regions 310-314 of FIG. 3 to form the trap rich layer regions 110-114. For example, the laser 620 may be applied to the first region 310 to form the first trap rich layer region 110, and the laser 620 may be applied to the second region 312 to form the second trap rich layer region 112. As described with reference to FIG. 1, the laser 620 may melt regions of the substrate 102 (e.g., the second silicon layer 105) to form the trap rich layer regions 110-114. The laser 620 may include a stealth dicing laser, an infrared laser, or another type of laser. As illustrate in FIG. 6B, the laser 620 applies the laser beam through the second surface 318 (e.g., the backside) of the substrate 102.

The laser stop layer 202 may prevent (or reduce) damage to the BOX layer 106 by the laser 620. To illustrate, the laser stop layer 202 may be impermeable (or have reduced permeability) to the laser beam due to the bandgap of the one or more dopants within the laser stop layer 202, as further described with reference to FIG. 2. Thus, the laser stop layer 202 may enable the trap rich layer regions 110-114 to be formed beneath the laser stop layer 202 while preventing the energy implantation of the laser 620 from reaching the BOX layer 106 (or reducing a magnitude of the energy that reaches the BOX layer 106). In this manner, the laser stop layer 202 may prevent (or reduce) damage to the BOX layer 106 from the laser 620.

Referring to FIG. 6C, a third illustrative diagram of at least one stage of the first process to form the device including one or more trap rich layer regions is shown and designated 604. As illustrated in FIG. 6C, after the laser 620 is applied to the regions 310-314, the trap rich layer regions 110-114 are formed. In other implementations, a single trap rich layer may be formed using the laser 620, as further described with reference to FIGS. 4A-4B.

The process of forming a device including one or more trap rich layer regions described with reference to FIGS. 6A-6C may reduce a risk of damage to the BOX layer 106, as compared to other techniques that do not include forming a laser stop layer within the substrate 102 prior to applying the laser 620. To illustrate, the laser stop layer 202 prevents the laser 620 from reaching the BOX layer 106 (or reduces a magnitude of the laser beam that reaches the BOX layer 106). Preventing the laser 620 from reaching the BOX layer 106 reduces or eliminates a risk of damage to the BOX layer 106 from being heated by the laser 620.

FIGS. 7A-C illustrate stages of a fourth illustrative process to form a device that includes one or more trap rich layer regions. In a particular implementation, the steps of the process may be initiated and/or performed by one or more devices described with reference to FIG. 12.

Referring to FIG. 7A, a first illustrative diagram of at least one stage of a fourth illustrative process to form a device that includes one or more trap rich layer regions is shown and designated 700. As illustrated in FIG. 7A, the substrate 102 may include the first silicon layer 103, the BOX layer 106, and the second silicon layer 105. Additionally, an ion implant trapper layer 730 may be formed within the substrate 102. For example, the ion implant trapper layer 730 may be formed within the substrate 102 by implantation, deposit, growth, etc. The ion implant trapper layer 730 may be configured to trap one or more ions that are implanted during formation of the trap rich layer regions 110-114, as further described with reference to FIG. 7B, which may improve the effectiveness of the trap rich layer regions 110-114. The ion implant trapper layer 730 may be formed beneath the BOX layer 106 (e.g., the ion implant trapper layer 730 may be located between the BOX layer 106 and the second silicon layer 105). In a particular implementation, the ion implant trapper layer 730 may be formed in direct contact with the BOX layer 106. The ion implant trapper layer 730 may be formed prior to forming the trap rich layer regions 110-114, as further described with reference to FIG. 7B. One or more components of the semiconductor device layer 104, such as the transistor 121 or the RF core 120, may be formed on the substrate 102 as part of one or more CMOS processing stages or FEOL processing stages.

Referring to FIG. 7B, a second illustrative diagram of at least one stage of the first process to form the device including one or more trap rich layer regions is shown and designated 702. As illustrated in FIG. 7B, the trap rich layer regions 110-114 are formed within the ion implant trapper layer 730. For example, an ion beam 720 may apply energy (e.g., implant ions or other high energy particles) to a first region 710 within the ion implant trapper layer 730 to form the first trap rich layer region 110, the ion beam 720 may apply energy to a second region 712 within the ion implant trapper layer 730 to form the second trap rich layer region 112, and the ion beam 720 may apply energy to a third region 714 within the ion implant trapper layer 730 to form the third trap rich layer region 114. The ion implant trapper layer 730 may include a layer of silicon that includes one or more dopants that enable more effective implantation of ions using an ion beam. For example, ion implantation using the ion beam 720 may be more effective at the ion implant trapper layer 730 than at the second silicon layer 105. Additionally or alternatively, the ion implant trapper layer 730 may enable formation of trap rich layer regions at lower temperatures as compared to forming trap rich layer regions in silicon. To illustrate, ions may be implanted in the ion implant trapper layer 730 faster than in silicon. Because the ions are implanted faster, the ion implant trapper layer 730 may be exposed to the ion beam 720 for a shorter duration, and thus the ion beam 720 does not heat the ion implant trapper layer 730 to as high a temperature.

Referring to FIG. 7C, a third illustrative diagram of at least one stage of the first process to form the device including one or more trap rich layer regions is shown and designated 704. As illustrated in FIG. 7C, after the ion beam 720 applies energy to the regions 710-714, the trap rich layer regions 110-114 are formed.

Although the ion beam 720 is illustrated in FIG. 7B as being applied through the second surface 318 (e.g., the backside) of the substrate 102, in other implementations, the ion beam 720 may be applied through the first surface 316 (e.g., a top surface) of the substrate 102. The ion beam may not cause significant damage to the semiconductor device layer 104. Applying the ion beam 720 through the first surface 316 to form the trap rich layer regions 110-114 uses less power than applying the ion beam 720 through the second surface 318 if the distance from the first surface 316 (or a top of the semiconductor device layer 104) to the ion implant trapper layer 730 is less than a distance from the second surface 318 to the ion implant trapper layer 730. Although the one or more components of the semiconductor device layer 104 are described as being formed prior to the application of energy by the ion beam 720, in other implementations, the ion beam 720 may be used to form the trap rich layer regions 110-114 prior to formation of the one or more components of the semiconductor device layer 104. Forming the trap rich layer regions 110-114 prior to formation of the one or more components of the semiconductor device layer 104 may reduce cost and complexity of MOL and BEOL processing stages.

The process of forming a device including one or more trap rich layer regions described with reference to FIGS. 7A-7C may form trap rich layer regions more effectively than forming trap rich layer regions within silicon. For example, the ion implant trapper layer 730 may trap more ions than silicon, resulting in trap rich layer regions with more implanted ions. Increasing the number of implanted ions in the trap rich layer regions increases the effectiveness of the trap rich layer regions. Additionally or alternatively, the ion implant trapper layer 730 may enable formation of trap rich layer regions at lower temperatures.

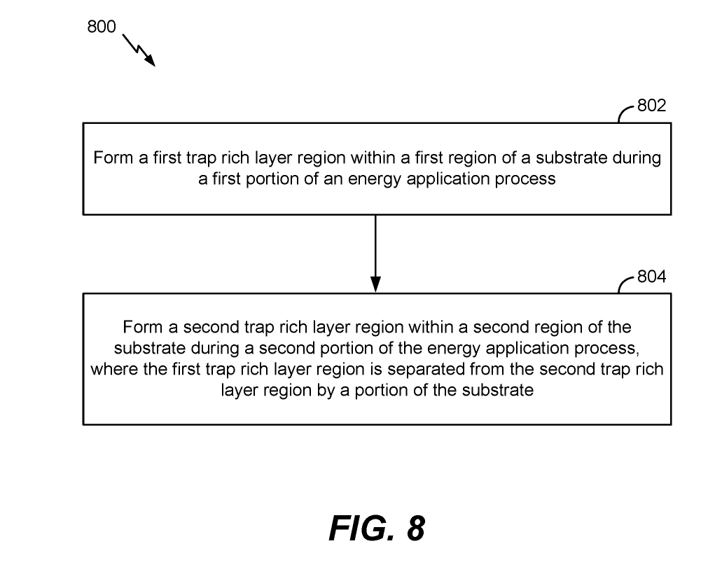

Referring to FIG. 8, a flow chart of an illustrative method of forming one or more trap rich layer regions is shown and generally designated 800. In a particular implementation, the method 800 may be a method of semiconductor fabrication that is initiated and/or performed by one or more devices described with reference to FIG. 12.

The method 800 includes forming a first trap rich layer region within a first region of a substrate during a first portion of an energy application process, at 802. For example, the first trap rich layer region may include or correspond to the first trap rich layer region 110 of FIGS. 1-2, 3C, 5C, 6C, and 7C, and the substrate may include or correspond to the substrate 102 of FIGS. 1-2, 3A-3C, 4A-4B, 5A-5C, 6A-6C, and 7A-7C. The energy application process may be performed using a laser or an ion beam, as non-limiting examples. The energy application process may include or correspond to a beam application process (e.g., a laser beam application process or an ion beam application process).

The method 800 further includes forming a second trap rich layer region within a second region of the substrate during a second portion of the energy application process, at 804. For example, the second trap rich layer region may include or correspond to the second trap rich layer region 112 of FIGS. 1-2, 3C, 5C, 6C, and 7C. The first trap rich layer region is separated from the second trap rich layer region by a portion of the substrate. For example, the portion of the substrate may include or correspond to the portion 116 of the substrate 102 of FIG. 1.

In a particular implementation, the method 800 includes forming an ion implant trapper layer in the substrate prior to forming the first trap rich layer region and the second trap rich layer region. For example, the ion implant trapper layer may include or correspond to the ion implant trapper layer 730 of FIG. 7. In another particular implementation, the method 800 includes forming one or more components of a semiconductor device layer on the substrate prior to forming the first trap rich layer region and the second trap rich layer region. For example, components of semiconductor device layers may be formed during CMOS processing stages that occur prior to formation of trap rich layer regions, as described with reference to FIGS. 3A and 5A. In a particular implementation, the semiconductor device layer is formed on a first surface of the substrate, and the energy is applied through an opposite surface of the substrate during the energy application process, as described with reference to FIG. 3B. In an alternate implementation, the energy is applied through the first surface during the energy application process, as described with reference to FIG. 5B.

Thus, the method 800 of FIG. 8 may reduce parasitic capacitance associated with a substrate by forming trap rich layer regions within the substrate. To illustrate, charge carrier traps within the trap rich layer regions may inhibit (or reduce) accumulation of charge carriers along a bottom surface of a BOX layer, which reduces (or eliminates) parasitic capacitance of the substrate. Reducing or eliminating parasitic capacitance may improve operation of one or more of the components of a semiconductor device layer formed on the substrate. For example, RF signal distortion at one or more components may be reduced. Forming the trap rich layer regions by applying energy (e.g., using a laser or an ion beam) reduces costs as compared to bonding a semiconductor device layer to a different substrate having a trap rich layer using a wafer-level layer transfer process.

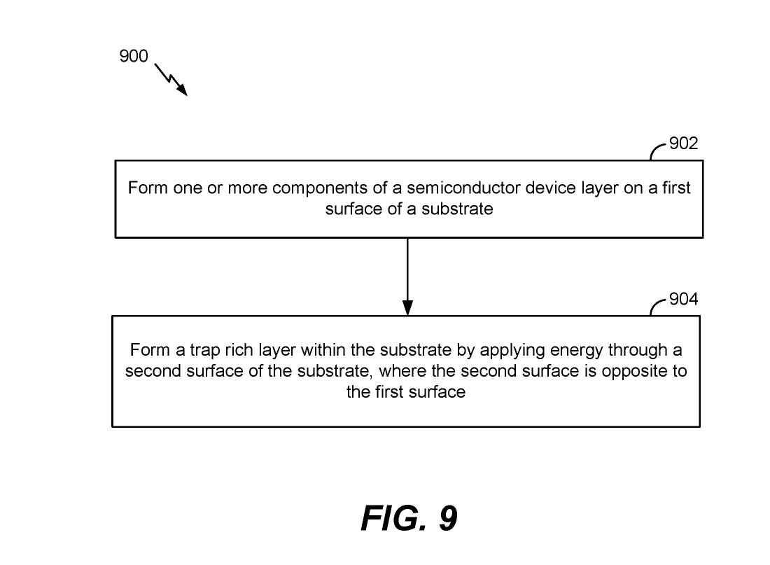

Referring to FIG. 9, a flow chart of an illustrative method of forming a trap rich layer is shown and generally designated 900. In a particular implementation, the method 900 may be initiated and/or performed by one or more devices described with reference to FIG. 12.

The method 900 includes forming one or more components of a semiconductor device layer on a first surface of a substrate, at 902. For example, the semiconductor device layer may include or correspond to the semiconductor device layer 104 of FIGS. 1-2, 3A-3C, 4A-4B, 5A-5C, 6A-6C, and 7A-7C, and the one or more components may include or correspond to the transistor 121, the RF core 120, or both, of FIG. 1.

The method 900 further includes forming a trap rich layer within the substrate by applying energy through a second surface of the substrate, at 904. For example, the trap rich layer may include or correspond to one or more of the trap rich layer regions 110-114 of FIGS. 1-2, 3C, 5C, 6C, and 7C or the trap rich layer 410 of FIG. 4. The second surface is opposite to the first surface. For example, energy may be applied through the second surface 318 (e.g., a backside) of the substrate 102 (instead of the first surface 316), as described with reference to FIG. 3B. The trap rich layer may be formed using a laser (e.g., a stealth dicing laser) or an ion beam, as non-limiting examples.

In a particular implementation, the method 900 includes, prior to forming the trap rich layer, forming a laser stop layer within the substrate by implanting one or more dopants within the substrate. For example, the laser stop layer may include or correspond to the laser stop layer 202 of FIGS. 2 and 6A-6C. The laser stop layer may be formed by implanting one or more dopants within a substrate, as described with reference to FIG. 6A, and the laser stop layer may prevent a laser beam from reaching a BOX layer within the substrate (or reduce a magnitude of the laser beam that reaches the BOX layer), as described with reference to FIG. 6B.

Thus, the method 900 of FIG. 9 reduces or eliminates degradation of a trap rich layer due to exposure to high temperatures. To illustrate, because the trap rich layer is formed by applying energy to a second surface (e.g., a backside) of a substrate, the trap rich layer may be formed after FEOL processing stages (including CMOS processing stages) without damaging one or more components of a semiconductor device layer formed on a first (e.g., top) surface of the substrate. Forming the trap rich layer regions after the FEOL processing stages prevents the trap rich layer regions from suffering degradation caused by exposure to high temperatures during FEOL processing stages.

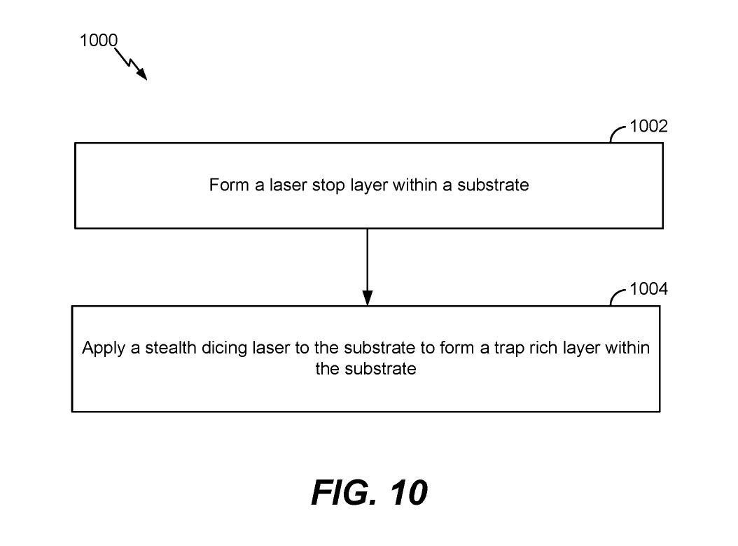

Referring to FIG. 10, a flow chart of an illustrative method of forming a trap rich layer using a stealth dicing laser is shown and generally designated 1000. In a particular implementation, the method 1000 may be initiated and/or performed by one or more devices described with reference to FIG. 12.

The method 1000 includes forming a laser stop layer within a substrate, at 1002. For example, the laser stop layer may include or correspond to the laser stop layer 202 of FIGS. 2 and 6A-6C, and the substrate may include or correspond to the substrate 102 of FIGS. 1-2, 3A-3C, 4A-4B, 5A-5C, 6A-6C, and 7A-7C. Forming the laser stop layer may include implanting one or more dopants (e.g., germanium, carbon, or a combination thereof) with the substrate.

The method 1000 further includes applying a laser to the substrate to form a trap rich layer within the substrate, at 1004. For example, the trap rich layer may include or correspond to the trap rich layer regions 110-114 of FIGS. 1-2, 3C, 5C, 6C, and 7C.

In a particular implementation, forming the trap rich layer includes applying the laser to a first region of the substrate to form a first trap rich layer region and applying the laser to a second region of the substrate to form a second trap rich layer region. For example, the first trap rich layer region may include or correspond to the first trap rich layer region 110 of FIGS. 1-2, 3C, 5C, 6C, and 7C, and the second trap rich layer region may include or correspond to the second trap rich layer region 112 of FIGS. 1-2, 3C, 5C, 6C, and 7C. Formation of the trap rich layer regions is described with reference to FIGS. 3B, 5B, 6B, and 7B.

Thus, the method 1000 of FIG. 10 forms a laser stop layer in a substrate that reduces a risk of damage to a BOX layer of the substrate from being heated by a laser. To illustrate, the laser stop layer prevents the laser from reaching the BOX layer (or reduces a magnitude of the laser that reaches the BOX layer) during formation of a trap rich layer. Preventing the laser from reaching the BOX layer reduces or eliminates a risk of damage to the BOX layer from being heated by the laser.

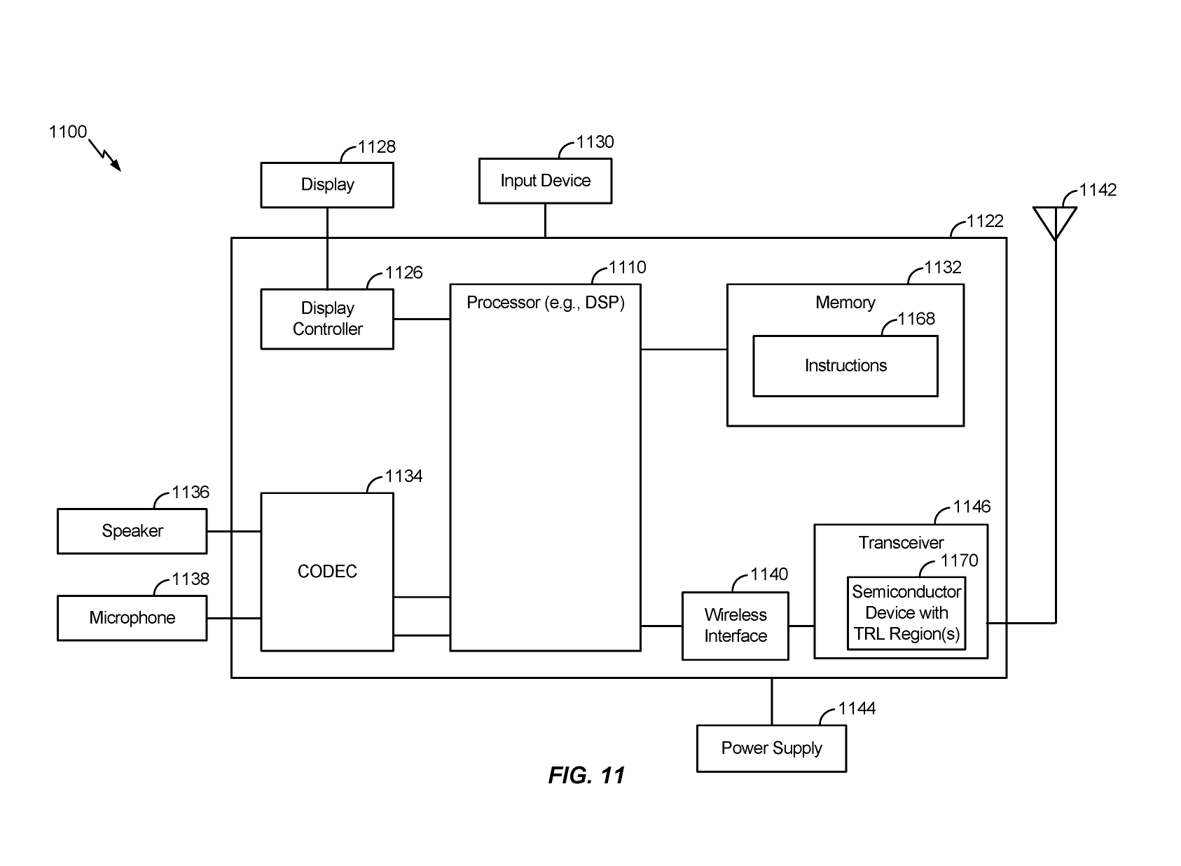

Referring to FIG. 11, a block diagram of a particular illustrative implementation of a device (e.g., a wireless communication device) is depicted and generally designated 1100. In various implementations, the device 1100 may have more or fewer components than illustrated in FIG. 11.

In a particular implementation, the device 1100 includes a processor 1110, such as a central processing unit (CPU) or a digital signal processor (DSP), coupled to a memory 1132. The memory 1132 includes instructions 1168 (e.g., executable instructions) such as computer-readable instructions or processor-readable instructions. The instructions 1168 may include one or more instructions that are executable by a computer, such as the processor 1110.

FIG. 11 also illustrates a display controller 1126 that is coupled to the processor 1110 and to a display 1128. A coder/decoder (CODEC) 1134 may also be coupled to the processor 1110. A speaker 1136 and a microphone 1138 may be coupled to the CODEC 1134.

FIG. 11 also illustrates that a wireless interface 1140, such as a wireless controller, and a transceiver 1146 may be coupled to the processor 1110 and to an antenna 1142, such that wireless data received via the antenna 1142, the transceiver 1146, and the wireless interface 1140 may be provided to the processor 1110. The transceiver 1146 may include a semiconductor device 1170 that includes one or more trap rich layer regions. In a particular implementation, the semiconductor device 1170 corresponds to the device 100 of FIG. 1 or the device 200 of FIG. 2.

In some implementations, the processor 1110, the display controller 1126, the memory 1132, the CODEC 1134, the semiconductor device 1170, the wireless interface 1140, and the transceiver 1146 are included in a system-in-package or system-on-chip device 1122. In some implementations, an input device 1130 and a power supply 1144 are coupled to the system-on-chip device 1122. Moreover, in a particular implementation, as illustrated in FIG. 11, the display 1128, the input device 1130, the speaker 1136, the microphone 1138, the antenna 1142, and the power supply 1144 are external to the system-on-chip device 1122. In a particular implementation, each of the display 1128, the input device 1130, the speaker 1136, the microphone 1138, the antenna 1142, and the power supply 1144 may be coupled to a component of the system-on-chip device 1122, such as an interface or a controller.

The device 1100 may include a headset, a mobile communication device, a smart phone, a cellular phone, a laptop computer, a computer, a tablet, a personal digital assistant, a display device, a television, a gaming console, a music player, a radio, a digital video player, a digital video disc (DVD) player, a tuner, a camera, a navigation device, a vehicle, a component of a vehicle, or any combination thereof.

In an illustrative implementation, the memory 1132 includes or stores the instructions 1168 (e.g., executable instructions), such as computer-readable instructions or processor-readable instructions. For example, the memory 1132 may include or correspond to a non-transitory computer readable medium storing the instructions 1168. The instructions 1168 may include one or more instructions that are executable by a computer, such as the processor 1110.

In conjunction with the described aspects, an apparatus includes means for reducing parasitic capacitance within a substrate. The means for reducing may include or correspond to the trap rich layer regions 110-114 of FIGS. 1-2, 3C, 5C, 6C, and 7C, the trap rich layer 410 of FIG. 4B, one or more other structures or circuits configured to reduce parasitic capacitance within a substrate, or any combination thereof.

The apparatus further includes means for performing one or more circuit functions. The means for performing may include or correspond to one or more components of the semiconductor device layer 104 of FIGS. 1-2, 3A-3C, 4A-4B, 5A-5C, 6A-6C, and 7A-7C, such as the transistor 121 or the RF core 120, one or more other structures or circuits configured to perform circuit functionality, or any combination thereof.

In a particular implementation, the apparatus further includes means for protecting an insulating layer of the substrate. The means for protecting may include or correspond to the laser stop layer 202 of FIGS. 2 and 6A-6C, one or more other structures or circuits configured to perform circuit functionality, or any combination thereof.

One or more of the disclosed aspects may be implemented in a system or an apparatus, such as the device 1100, that may include a communications device, a fixed location data unit, a mobile location data unit, a mobile phone, a cellular phone, a satellite phone, a computer, a tablet, a portable computer, a display device, a media player, or a desktop computer. Alternatively or additionally, the device 1100 may include a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, a satellite, a vehicle, a component integrated within a vehicle, any other device that includes a processor or that stores or retrieves data or computer instructions, or a combination thereof. As another illustrative, non-limiting example, the system or the apparatus may include remote units, such as hand-held personal communication systems (PCS) units, portable data units such as global positioning system (GPS) enabled devices, meter reading equipment, or any other device that includes a processor or that stores or retrieves data or computer instructions, or any combination thereof.

While FIG. 11 illustrates the transceiver 1146 as including the semiconductor device 1170 (e.g., a semiconductor device including one or more trap rich layer regions), any component of a device, such as the device 1100, may include the semiconductor device 1170. For example, the wireless interface 1140, the processor 1110, the memory 1132, the input device 1130, the display 1128, the display controller 1126, or any other electronic device may include the semiconductor device 1170.

While FIG. 11 illustrates a wireless communication device including a semiconductor device that includes one or more trap rich layer regions, a semiconductor device that includes one or more trap rich layer regions may be included in various other electronic devices. For example, a semiconductor device as described with references to FIGS. 1-11, may be included in one or more components of a base station.

A base station may be part of a wireless communication system. The wireless communication system may include multiple base stations and multiple wireless devices. The wireless communication system may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA.

Various functions may be performed by one or more components of the base station, such as sending and receiving messages and data (e.g., audio data). The one or more components of the base station may include a processor (e.g., a CPU), a transcoder, a memory, a network connection, a media gateway, a demodulator, a transmission data processor, a receiver data processor, a transmission multiple input-multiple output (MIMO) processor, transmitters and receivers (e.g., transceivers), an array of antennas, or a combination thereof. One or more of the components of the base station may include a semiconductor device that includes one or more trap rich layer regions, as described above with reference to FIGS. 1-11.

During operation of a base station, one or more antennas of the base station may receive a data stream from a wireless device. A transceiver may receive the data stream from the one or more antennas and may provide the data stream to the demodulator. In a particular implementation, the transceiver may include a semiconductor device that includes one or more trap rich layer regions, as described above with reference to FIGS. 1-11. The demodulator may demodulate modulated signals of the data stream and provide demodulated data to the receiver data processor. The receiver data processor may extract audio data from the demodulated data and provide the extracted audio data to the processor.

The processor may provide the audio data to the transcoder for transcoding. The decoder of the transcoder may decode the audio data from a first format into decoded audio data and the encoder may encode the decoded audio data into a second format. In some implementations, the encoder may encode the audio data using a higher data rate (e.g., upconvert) or a lower data rate (e.g., downconvert) than received from the wireless device. In other implementations the audio data may not be transcoded. Transcoding operations (e.g., decoding and encoding) may be performed by multiple components of the base station. For example, decoding may be performed by the receiver data processor and encoding may be performed by the transmission data processor. In other implementations, the processor may provide the audio data to the media gateway for conversion to another transmission protocol, coding scheme, or both. The media gateway may provide the converted data to another base station or core network via the network connection.

The foregoing disclosed devices and functionalities may be designed and configured into computer files (e.g. RTL, GDSII, GERBER, etc.) stored on computer readable media. Some or all such files may be provided to fabrication handlers to fabricate devices based on such files. Resulting products include semiconductor wafers that are then cut into semiconductor dies and packaged into semiconductor chips. The semiconductor chips are then employed in devices described above. FIG. 12 depicts a particular illustrative implementation of an electronic device manufacturing process 1200.

Physical device information 1202 is received at the manufacturing process 1200, such as at a research computer 1206. The physical device information 1202 may include design information representing at least one physical property of a semiconductor device, such as a semiconductor device including one or more trap rich layer regions. For example, the physical device information 1202 may include physical parameters, material characteristics, and structure information that is entered via a user interface 1204 coupled to the research computer 1206. The research computer 1206 includes a processor 1208, such as one or more processing cores, coupled to a computer readable medium (e.g., a non-transitory computer readable medium) such as a memory 1210. The memory 1210 may store computer readable instructions that are executable to cause the processor 1208 to transform the physical device information 1202 to comply with a file format and to generate a library file 1212.

In a particular implementation, the library file 1212 includes at least one data file including the transformed design information. For example, the library file 1212 may include a library of semiconductor devices including the semiconductor device including one or more trap rich layer regions that is provided for use with an electronic design automation (EDA) tool 1220.

The library file 1212 may be used in conjunction with the EDA tool 1220 at a design computer 1214 including a processor 1216, such as one or more processing cores, coupled to a memory 1218. The EDA tool 1220 may be stored as processor executable instructions at the memory 1218 to enable a user of the design computer 1214 to design a circuit including the semiconductor device including one or more trap rich layer regions of the library file 1212. For example, a user of the design computer 1214 may enter circuit design information 1222 via a user interface 1224 coupled to the design computer 1214. The circuit design information 1222 may include design information representing at least one physical property of a semiconductor device, such as the semiconductor device including one or more trap rich layer regions. To illustrate, the circuit design property may include identification of particular circuits and relationships to other elements in a circuit design, positioning information, feature size information, interconnection information, or other information representing a physical property of a semiconductor device.

The design computer 1214 may be configured to transform the design information, including the circuit design information 1222, to comply with a file format. To illustrate, the file formation may include a database binary file format representing planar geometric shapes, text labels, and other information about a circuit layout in a hierarchical format, such as a Graphic Data System (GDSII) file format. The design computer 1214 may be configured to generate a data file including the transformed design information, such as a GDSII file 1226 that includes information describing the semiconductor device including one or more trap rich layer regions, in addition to other circuits or information. To illustrate, the data file may include information corresponding to a system-on-chip (SOC) that includes the semiconductor device including one or more trap rich layer regions and that also includes additional electronic circuits and components within the SOC.

The GDSII file 1226 may be received at a fabrication process 1228 to manufacture the semiconductor device including one or more trap rich layer regions, according to transformed information in the GDSII file 1226. For example, a device manufacture process may include providing the GDSII file 1226 to a mask manufacturer 1230 to create one or more masks, such as masks to be used with photolithography processing, illustrated as a representative mask 1232. The mask 1232 may be used during the fabrication process 1228 to generate one or more wafers 1233, which may be tested and separated into dies, such as a representative die 1236. The die 1236 includes a circuit including the semiconductor device including one or more trap rich layer regions.

For example, the fabrication process 1228 may include a processor 1234 and a memory 1235 to initiate and/or control the fabrication process 1228. The memory 1235 may include executable instructions such as computer-readable instructions or processor-readable instructions. The executable instructions may include one or more instructions that are executable by a computer such as the processor 1234.

The fabrication process 1228 may be implemented by a fabrication system that is fully automated or partially automated. For example, the fabrication process 1228 may be automated according to a schedule. The fabrication system may include fabrication equipment (e.g., processing tools) to perform one or more operations to form a semiconductor device. For example, deposit one or more materials, epitaxially grow one or more materials, conformally deposit one or more materials, apply a hardmask, apply an etching mask, perform etching, perform planarization, form a dummy gate stack, form a gate stack, perform a standard clean 1 type, etc.

The fabrication system (e.g., an automated system that performs the fabrication process 1228) may have a distributed architecture (e.g., a hierarchy). For example, the fabrication system may include one or more processors, such as the processor 1234, one or more memories, such as the memory 1235, and/or controllers that are distributed according to the distributed architecture. The distributed architecture may include a high-level processor that controls or initiates operations of one or more low-level systems. For example, a high-level portion of the fabrication process 1228 may include one or more processors, such as the processor 1234, and the low-level systems may each include or may be controlled by one or more corresponding controllers. A particular controller of a particular low-level system may receive one or more instructions (e.g., commands) from a high-level system, may issue sub-commands to subordinate modules or process tools, and may communicate status data back to the high-level system. Each of the one or more low-level systems may be associated with one or more corresponding pieces of fabrication equipment (e.g., processing tools). In a particular aspect, the fabrication system may include multiple processors that are distributed in the fabrication system. For example, a controller of a low-level system component of the fabrication system may include a processor, such as the processor 1234.

Alternatively, the processor 1234 may be a part of a high-level system, subsystem, or component of the fabrication system. In another aspect, the processor 1234 includes distributed processing at various levels and components of a fabrication system.

Thus, the processor 1234 may include processor-executable instructions that, when executed by the processor 1234, cause the processor 1234 to initiate or control formation of a semiconductor device including one or more trap rich layer regions. In a particular aspect, the processor 1234 may perform operations including initiating formation of a first trap rich layer region within a substrate by applying energy to a first region of the substrate. The operations may further include initiating formation of a second trap rich layer region within the substrate by applying energy to a second region of the substrate. The first trap rich layer region may be separated from the second trap rich layer region by a portion of the substrate.

Additionally or alternatively, the processor 1234 may perform operations including initiating formation of one or more components of a semiconductor device layer on a first surface of a substrate. The operations may further include initiating formation of a trap rich layer within the substrate by applying energy through a second surface of the substrate, wherein the second surface is opposite to the first surface. Additionally or alternatively, the processor 1234 may perform operations including initiating formation of a laser stop layer within a substrate. The operations may further include initiating application of a laser to the substrate to form a trap rich layer within the substrate.

One or more of the operations may be performed by controlling one of more deposition tools, such as a molecular beam epitaxial growth tool, a flowable chemical vapor deposition (FCVD) tool, a conformal deposition tool, or a spin-on deposition tool, one or more removal tools, such as a chemical removal tool, a reactive gas removal tool, a hydrogen reaction removal tool, or a standard clean 1 type removal tool, one or more etchers, such as a wet etcher, a dry etcher, or a plasma etcher, one or more dissolving tools, such as a developer or developing tool, one or more layer transfer tools, such as a plasma activation tool or other activation tool, one or more other tools, one or more energy implantation tools, such as a laser or an ion beam, or a combination thereof.

The executable instructions included in the memory 1235 may enable the processor 1234 to initiate formation of a semiconductor device such as the semiconductor device including one or more trap rich layer regions. In a particular implementation, the memory 1235 is a non-transitory computer readable medium storing processor-executable instructions that are executable by the processor 1234 to cause the processor 1234 to perform the above-described operations.

The die 1236 may be provided to a packaging process 1238 where the die 1236 is incorporated into a representative package 1240. For example, the package 1240 may include the single die 1236 or multiple dies, such as a system-in-package (SiP) arrangement. The package 1240 may be configured to conform to one or more standards or specifications, such as Joint Electron Device Engineering Council (JEDEC) standards.

Information regarding the package 1240 may be distributed to various product designers, such as via a component library stored at a computer 1246. The computer 1246 may include a processor 1248, such as one or more processing cores, coupled to a memory 1250. A printed circuit board (PCB) tool may be stored as processor executable instructions at the memory 1250 to process PCB design information 1242 received from a user of the computer 1246 via a user interface 1244. The PCB design information 1242 may include physical positioning information of a packaged semiconductor device on a circuit board, the packaged semiconductor device corresponding to the package 1240 including the semiconductor device including one or more trap rich layer regions.

The computer 1246 may be configured to transform the PCB design information 1242 to generate a data file, such as a GERBER file 1252 with data that includes physical positioning information of a packaged semiconductor device on a circuit board, as well as layout of electrical connections such as traces and vias, where the packaged semiconductor device corresponds to the package 1240 including the semiconductor device including one or more trap rich layer regions. In other implementations, the data file generated by the transformed PCB design information 1242 may have a format other than a GERBER format.

The GERBER file 1252 may be received at a board assembly process 1254 and used to create PCBs, such as a representative PCB 1256, manufactured in accordance with the design information stored within the GERBER file 1252. For example, the GERBER file 1252 may be uploaded to one or more machines to perform various steps of a PCB production process. The PCB 1256 may be populated with electronic components including the package 1240 to form a representative printed circuit assembly (PCA) 1258.

The PCA 1258 may be received at a product manufacture process 1260 and integrated into one or more electronic devices, such as a first representative electronic device 1262 and a second representative electronic device 1264. For example, the first representative electronic device 1262, the second representative electronic device 1264, or both, may include or correspond to the wireless communication device 1100 of FIG. 11. As an illustrative, non-limiting example, the first representative electronic device 1262, the second representative electronic device 1264, or both, may include or correspond to a communications device, a fixed location data unit, a mobile location data unit, a mobile phone, a cellular phone, a satellite phone, a computer, a tablet, a portable computer, or a desktop computer. Alternatively or additionally, the first representative electronic device 1262, the second representative electronic device 1264, or both, may include a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, a vehicle (or a component thereof), any other device that stores or retrieves data or computer instructions, or a combination thereof, into which the semiconductor device including one or more trap rich layer regions is integrated. As another illustrative, non-limiting example, one or more of the electronic devices 1262 and 1264 may include remote units, such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 12 illustrates remote units according to teachings of the disclosure, the disclosure is not limited to these illustrated units. Aspects of the disclosure may be suitably employed in any device which includes active integrated circuitry including memory and on-chip circuitry.

A device that includes the semiconductor device including one or more trap rich layer regions may be fabricated, processed, and incorporated into an electronic device, as described in the illustrative process 1200. One or more aspects disclosed with respect to FIGS. 1-11 may be included at various processing stages, such as within the library file 1212, the GDSII file 1226, and the GERBER file 1252, as well as stored at the memory 1210 of the research computer 1206, the memory 1218 of the design computer 1214, the memory 1250 of the computer 1246, the memory of one or more other computers or processors (not shown) used at the various stages, such as at the board assembly process 1254, and also incorporated into one or more other physical implementations such as the mask 1232, the die 1236, the package 1240, the PCA 1258, other products such as prototype circuits or devices (not shown), or any combination thereof. Although various representative stages are depicted with reference to FIGS. 1-7, in other implementations fewer stages may be used or additional stages may be included. Similarly, the process 1200 of FIG. 12 may be performed by a single entity or by one or more entities performing various stages of the process 1200.

Although one or more of FIGS. 1-12 may illustrate systems, apparatuses, and/or methods according to the teachings of the disclosure, the disclosure is not limited to these illustrated systems, apparatuses, and/or methods. One or more functions or components of any of FIGS. 1-12 as illustrated or described herein may be combined with one or more other portions of another of FIGS. 1-12. For example, one or more steps of the method 800 of FIG. 8 may be performed in combination with the method 900 of FIG. 9 or the method 1000 of FIG. 10. Accordingly, no single implementation described herein should be construed as limiting and implementations of the disclosure may be suitably combined without departing form the teachings of the disclosure. As an example, one or more operations described with reference to FIGS. 8-10 may be optional, may be performed at least partially concurrently, and/or may be performed in a different order than shown or described.

Those of skill would further appreciate that the various illustrative logical blocks, configurations, modules, circuits, and algorithm steps described in connection with the implementations disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the disclosure herein may be implemented directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description is provided to enable a person skilled in the art to make or use the disclosed implementations. Various modifications to these implementations will be readily apparent to those skilled in the art, and the principles defined herein may be applied to other implementations without departing from the scope of the disclosure. Thus, the present disclosure is not intended to be limited to the implementations shown herein but is to be accorded the widest scope possible consistent with the principles and novel features as defined by the following claims.

1. A device comprising:
a substrate comprising a first trap rich layer region and a second trap rich layer region, wherein the first trap rich layer region is separated from the second trap rich layer region by a portion of the substrate; and
a semiconductor device layer including one or more components, the one or more components including a first component, wherein the first component is aligned with at least a portion of the first trap rich layer region.

2. The device of claim 1, wherein the first trap rich layer region and the second trap rich layer region comprise high resistance polysilicon, and wherein the first trap rich layer region and the second trap rich layer region each include electrically active charge carrier traps.

3. The device of claim 1, wherein the substrate further comprises a buried oxide (BOX) layer located between the first trap rich layer region and the semiconductor device layer.

4. The device of claim 3, wherein a surface of the first trap rich layer region is in direct contact with the BOX layer.

5. The device of claim 1, wherein the substrate further comprises a laser stop layer located between the first trap rich layer region and the semiconductor device layer, the laser stop layer including at least one dopant.

6. The device of claim 5, wherein a surface of the first trap rich layer region is in direct contact with the laser stop layer.

7. The device of claim 5, wherein the at least one dopant includes germanium.

8. The device of claim 5, wherein the at least one dopant includes carbon.

9. The device of claim 1, wherein the first trap rich layer region and the second trap rich layer region include implanted ions.

10. The device of claim 1, the substrate further comprising:
a first silicon layer of the substrate located between the semiconductor device layer and the first trap rich layer region; and
a second silicon layer of the substrate, wherein the first trap rich layer region is located between the first silicon layer and the second silicon layer, and wherein the first trap rich layer region has a rough interface with the second silicon layer.

11. (canceled)

12. The device of claim 10, wherein the one or more components include a transistor, a radio frequency (RF) core, or a combination thereof, and wherein the first silicon layer is located between the first trap rich layer region and a gate of the transistor, and wherein the first silicon layer is located between the second trap rich layer region and the RF core.

13. (canceled)

14. The device of claim 1, wherein the substrate and the semiconductor device layer are integrated in a transceiver, and wherein the transceiver is included in a mobile device.

15. The device of claim 1, wherein the substrate and the semiconductor device layer are integrated in a transceiver, and wherein the transceiver is included in a base station.

16. A method of semiconductor fabrication, the method comprising:
forming a first trap rich layer region within a first region of a substrate during a first portion of an energy application process; and
forming a second trap rich layer region within a second region of the substrate during a second portion of the energy application process, wherein the first trap rich layer region is separated from the second trap rich layer region by a portion of the substrate.

17. The method of claim 16, wherein the energy application process is performed using a laser or using an ion beam.

18. (canceled)

19. The method of claim 16, further comprising forming an ion implant trapper layer in the substrate prior to forming the first trap rich layer region and the second trap rich layer region, wherein the first trap rich layer region and the second trap rich layer region are formed within the ion implant trapper layer.

20. The method of claim 16, further comprising forming one or more components of a semiconductor device layer on the substrate prior to forming the first trap rich layer region and the second trap rich layer region, the one or more components including a first component, wherein the first component is aligned with at least a portion of the first trap rich layer region.

21. The method of claim 20, wherein the semiconductor device layer is formed on a first surface of the substrate, and wherein energy is applied through an opposite surface of the substrate during the energy application process.

22. The method of claim 20, wherein the semiconductor device layer is formed on a first surface of the substrate, and wherein energy is applied through the first surface of the substrate during the energy application process.

23. A method of semiconductor fabrication, the method comprising:
forming one or more components of a semiconductor device layer on a first surface of a substrate; and
forming a trap rich layer within the substrate by applying energy through a second surface of the substrate, wherein the second surface is opposite to the first surface.

24. The method of claim 23, wherein the trap rich layer is formed using a stealth dicing laser.

25. The method of claim 24, further comprising, prior to forming the trap rich layer, forming a laser stop layer within the substrate by implanting one or more dopants within the substrate.

26. The method of claim 23, wherein the trap rich layer is formed using an ion beam.

27. The method of claim 23, wherein forming the trap rich layer comprises:
applying energy through a first region of the second surface to form a first trap rich layer region, wherein the one or more components include a first component, wherein the first component is aligned with at least a portion of the first trap rich layer region;
applying energy through a second region of the second surface to form a second trap rich layer region, wherein the first trap rich layer region is separated from the second trap rich layer region by a portion of the substrate; and
applying energy through a third region of the second surface to form a third trap rich layer region, wherein the first trap rich layer region is separated from the third trap rich layer region by a second portion of the substrate.

28. A method of semiconductor fabrication, the method comprising:
forming a laser stop layer within a substrate; and
applying a laser to the substrate to form a trap rich layer within the substrate.

29. The method of claim 28, wherein forming the trap rich layer comprises:
applying the laser to a first region of the substrate to form a first trap rich layer region; and
applying the laser to a second region of the substrate to form a second trap rich layer region, wherein the first trap rich layer region is separated from the second trap rich layer region by a portion of the substrate.

30. The method of claim 28, wherein forming the laser stop layer comprises implanting one or more dopants within the substrate, wherein the one or more dopants include germanium, carbon, or a combination thereof.

31. The device of claim 1, wherein the first component comprises a transistor, and wherein a gate of the transistor is aligned with the first trap rich layer region with respect to a first direction, the first direction orthogonal to a second direction along an interface between the first trap rich layer region and a second silicon layer of the substrate.

32. The device of claim 1, wherein the first component comprises a radio frequency (RF) core, and wherein the RF core is aligned with the first trap rich layer region with respect to a first direction, the first direction orthogonal to a second direction along an interface between the first trap rich layer region and a second silicon layer of the substrate.

33. The device of claim 1, wherein the portion of the substrate that separates the first trap rich layer region from the second trap rich layer region comprises a portion of an ion implant trapper layer of the substrate.
